(19) United States
(12) Patent Application Publication
(10) Pub. No.: US 2009/0152657 A1
(43) Pub. Date: Jun. 18, 2009

(54) MAGNETIC FIELD DETECTOR

(76) Inventors: Jeongdae Suh, Daejeon-city (KR); Myungae Chung, Daejeon-city (KR)

Correspondence Address: LADAS & PARRY LLP, 224 SOUTH MICHIGAN AVENUE, SUITE 1600, CHICAGO, IL, 60604, US

(21) Appl. No.: 12/170,744

(22) Filed: Jul. 10, 2008

(30) Foreign Application Priority Data
Dec. 14, 2007 (KR) 10-2007-0131069

(51) Int. Cl. H01L 29/82

(52) U.S. Cl. 257/421; 257/E29.323

(57) ABSTRACT

Disclosed is a magnetic field detector having various structures that can be used as a high-density magnetic biosensor. An embodiment of the invention provides a magnetic field detector using a thin film for detecting magnetic beads. The magnetic field detector includes: a substrate; a magnetoresistive element that is formed on an upper surface of the substrate in a ring shape using the thin film; electrodes that are formed on the upper surface of the substrate to be connected to the magnetoresistive element; a protective layer that is formed on the magnetoresistive element and the electrodes; and a magnetic bead limiting layer that is formed on an upper surface of the protective layer to cover the entire surface of the magnetoresistive element and portions of the electrodes.

### BACKGROUND OF THE INVENTION

1. Field of the Invention

The present invention relates to a magnetic field detector, and more particularly, to a magnetic field detector that detects a weak magnetic field generated from magnetic beads having a size of several tens of nanometers to several micrometers.

This work was supported by the IT R&D program of MIC/IITA [2006-S-074-02, High Performance Bio-sensor System Using Nano-particles].

2. Description of the Related Art

Micro devices and array devices using the same have had a great effect on the analysis of DNA, RNA, protein, viruses, and bacteria. In order to effectively analyze these bio-molecules, researches on magnetic biosensors using spherical magnetic particles (hereinafter, referred to as “magnetic beads”) having a size of several tens of nanometers to several micrometers have been conducted.

The magnetic biosensor includes a magnetic field detector provided with a biochemical layer capable of being coupled to specific molecules. The magnetic biosensor performs analysis using magnetic beads, which are superparamagnetic particles to which biochemical molecules are coupled and have a size of several nanometers to several micrometers. When an analytical solution containing the magnetic beads is dropped on the magnetic field detector, specific binding occurs between capture molecules on the surface of the magnetic field detector and target bio-molecules on the surfaces of the magnetic beads. When an external magnetic field is applied to the magnetic beads to magnetize the magnetic beads, the magnetic field detector detects the magnetic field generated from the magnetic beads, thereby indirectly detecting the bio-molecules.

As the magnetic bead detecting device using the magnetoresistive element according to the related art, the following have been proposed: linear magnetic field detectors each having triangular structures at both ends and an array thereof (M. C. Tondra, U.S. Pat. No. 6,875,621B2); a linear magnetic field detector having a hemispherical structure at one end (G. Li, et al., Journal of Applied Physics 93, 7557 (2003)); a magnetic field detector including linear magnetoresistive elements connected to each other (J. C. Rife, et al., Sensors and Actuators, A107, 209 (2003); a magnetic field detector including linear magnetoresistive element having a spiral shape (Biosensors and Bioelectronics 19, 1149 (2004); and a magnetic field detector including a linear magnetoresistive element having a U shape (H. A. Ferreira et al., Journal of Applied Physics 99, 08P105 (2006)).

In general, the magnetic field detector for detecting the magnetic beads according to the related art uses the above-mentioned linear magnetoresistive element. When the magnetic field detector with the linear structure is used, mutual interference occurs due to a stray field that is generated from the magnetic field detector magnetized by an external magnetic field. That is, the linear magnetoresistive element having a flat upper surface is used in the magnetic field detector according to the related art. Therefore, when an external magnetic field is applied, the magnetization direction of the element is fixed from one end to the other end thereof, which causes the leakage of the magnetic field to the outside of the element, that is, a stray field. The stray field lowers the SN ratio and has an adverse effect on the stability of the magnetic field detector. As a result, the magnetic field detector using the linear magnetoresistive element is not suitable as a high-density magnetic field detector.

### SUMMARY OF THE INVENTION

The invention is designed to solve the problems, and an object of the invention is to provide a magnetic field detector with various structures capable of being used as a high-density magnetic biosensor.

In order to achieve the object, according to an aspect of the invention, a magnetic field detector includes a magnetoresistive element that is formed in any one of a circular ring shape, an elliptical ring shape, a square ring shape, and a rectangular ring shape.

According to another aspect of the invention, there is provided a magnetic field detector using a thin film for detecting magnetic beads. The magnetic field detector includes: a substrate; a magnetoresistive element that is formed on an upper surface of the substrate in a ring shape using the thin film; electrodes that are formed on the upper surface of the substrate to be connected to the magnetoresistive element; a protective layer that is formed on the magnetoresistive element and the electrodes; and a magnetic bead limiting layer that is formed on an upper surface of the protective layer to cover the entire surface of the magnetoresistive element and portions of the electrodes.

The thin film may be formed of any one of a giant magnetoresistive thin film, an anisotropic magnetoresistive thin film, a spin valve thin film, and a tunnel-type magnetoresistive thin film.

The thin film may include a pinned layer and a free layer.

The thin film may be a laminate of a seed layer, an antiferromegnetic layer, a pinned layer, a gap layer, a free layer, and a protective layer formed in this order.

The seed layer may be formed of Ta.

The antiferromegnetic layer may be formed of IrMn.

The pinned layer may be formed of Ni₈₀Fe₂₀ or Co₈₀Fe₂₀.

The gap layer may be formed of Cu.

The free layer may be formed of Ni₈₀Fe₂₀ or Co₈₀Fe₂₀.

The protective layer may be formed of Ta.

The magnetoresistive element may be formed in any one of a circular ring shape, an elliptical ring shape, a square ring shape, and a rectangular ring shape.

The electrodes may be formed of Ta or Au.

The electrodes may be formed so as to be horizontally connected to the magnetoresistive element.

The electrodes may be formed so as to be vertically and horizontally connected to the magnetoresistive element.

The protective layer may be formed of SiO₂ or Si₃N₄.

The protective layer may be formed with a thickness of 50 to 300 nm at room temperature.

The magnetic bead limiting layer may be formed of a photosensitive thin film.

The magnetic bead limiting layer may be formed with a thickness of 1 to 2 μm at room temperature.

The outside diameter of the magnetoresistive element may be in a range of 100 nm to 30 μm.

The width of the magnetoresistive element may be in a range of 100 nm to 5 μm.

A plurality of magnetoresistive elements may be formed in a one-dimensional array.

A plurality of magnetoresistive elements may be formed in a two-dimensional array, that is, in a matrix.

According to the manufacturing method of the above-described aspect of the invention, since a stray field is formed inside the magnetoresistive element having a circular ring shape, an elliptical ring shape, a square ring shape, or a rectangular ring shape, the stray field does not leak to the outside of the magnetic field detector. Therefore, there is no mutual interference due to the stray field.

In particular, since the magnetic bead limiting layer limits the generation of the stray field caused by an external magnetic field inside the magnetoresistive element, the operation of the magnetic field detector can be sufficiently stable to detect bio-molecules on a magnetic biosensor chip.

According to the manufacturing method of the above-described aspect of the invention, it is possible to improve the performance of a magnetic field detector, and manufacture a high-density magnetic field detector.

### BRIEF DESCRIPTION OF THE DRAWINGS

FIGS. 1A to 1C are diagrams illustrating the laminated structure of a giant magnetoresistive thin film according to the invention;

FIGS. 2A to 8B are diagrams sequentially illustrating the structure of a magnetic field detector according to a first embodiment of the invention and a method of manufacturing the same;

FIG. 9 is a graph illustrating the relationship between a voltage and a magnetic field applied to the magnetic field detector provided with a magnetoresistive element having a circular ring shape according to the first embodiment;

FIGS. 10A to 16B are diagrams sequentially illustrating the structure of a magnetic field detector according to a second embodiment of the invention and a method of manufacturing the same;

FIGS. 17A to 23B are diagrams sequentially illustrating the structure of a magnetic field detector according to a third embodiment of the invention and a method of manufacturing the same;

FIGS. 24A to 30B are diagrams sequentially illustrating the structure of a magnetic field detector according to a fourth embodiment of the invention and a method of manufacturing the same;

FIGS. 31A to 37B are diagrams sequentially illustrating the structure of a magnetic field detector according to a fifth embodiment of the invention and a method of manufacturing the same;

FIGS. 38A to 44B are diagrams sequentially illustrating the structure of a magnetic field detector according to a sixth embodiment of the invention and a method of manufacturing the same;

FIGS. 45A and 45B are diagrams illustrating a modification of the first embodiment;

FIG. 46 is a graph illustrating the relationship between a voltage and a magnetic field applied to a magnetic field detector provided with a magnetoresistive element having an elliptical ring shape shown in FIGS. 45A and 45B;

FIGS. 47A and 47B are diagrams illustrating a modification of the second embodiment;

FIGS. 48A and 48B are diagrams illustrating a modification of the third embodiment;

FIGS. 49A and 49B are diagrams illustrating a modification of the fourth embodiment;

FIGS. 50A and 50B are diagrams illustrating a modification of the fifth embodiment;

FIGS. 51A and 51B are diagrams illustrating a modification of the sixth embodiment;

FIGS. 52A and 52B are diagrams illustrating another modification of the first embodiment;

FIG. 53 is a graph illustrating the relationship between a voltage and a magnetic field applied to a magnetic field detector provided with a magnetoresistive element having a square ring shape shown in FIGS. 52A and 52B;

FIGS. 54A and 54B are diagrams illustrating another modification of the second embodiment;

FIGS. 55A and 55B are diagrams illustrating another modification of the third embodiment;

FIGS. 56A and 56B are diagrams illustrating another modification of the fourth embodiment;

FIGS. 57A and 57B are diagrams illustrating another modification of the fifth embodiment;

FIGS. 58A and 58B are diagrams illustrating another modification of the sixth embodiment;

FIGS. 59A and 59B are diagrams illustrating still another modification of the first embodiment;

FIGS. 60A and 60B are diagrams illustrating still another modification of the second embodiment;

FIGS. 61A and 61B are diagrams illustrating still another modification of the third embodiment;

FIGS. 62A and 62B are diagrams illustrating still another modification of the fourth embodiment;

FIGS. 63A and 63B are diagrams illustrating still another modification of the fifth embodiment; and

FIGS. 64A and 64B are diagrams illustrating still another modification of the sixth embodiment.

### DESCRIPTION OF THE PREFERRED EMBODIMENTS

Hereinafter, magnetic field detectors according to embodiments of the invention will be described with reference to the accompanying drawings.

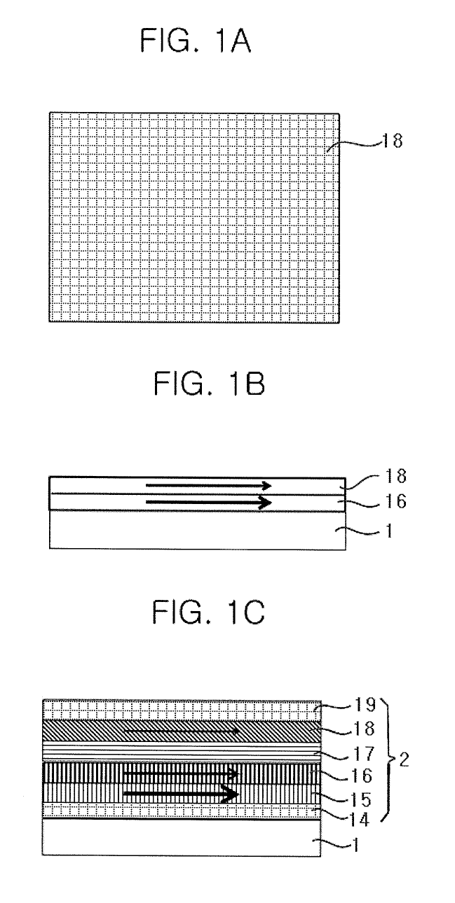

FIGS. 1A to 1C are diagrams illustrating the laminated structure of a giant magnetoresistive thin film according to an embodiment of the invention. In FIG. 1C, a substrate 1 is a Si or SiO₂ single crystal substrate. A SiO₂ oxidation layer is formed on the surface of the substrate 1. A giant magnetoresistive thin film 2 having a laminated structure of a seed layer, a free layer, a gap layer, a pinned layer, an antiferromegnetic layer, and a protective layer is formed on an upper surface of the substrate 1 by vapor deposition. For example, a seed layer 14 is formed on the upper surface of the substrate 1, and an antiferromegnetic layer 15 is formed on an upper surface of the seed layer 14. A pinned layer 16 is formed on an upper surface of the antiferromegnetic layer 15, and a gap layer 17 is formed on an upper surface of the pinned layer 16. A free layer 18 is formed on an upper surface of the gap layer 17, and a protective layer 19 is formed on an upper surface of the free layer 18.

The seed layer 14 and the protective layer 19 are formed of, for example, Ta with a thickness of about 5 nm. The antiferromegnetic layer 15 is formed of, for example, IrMn, and the thickness of the antiferromegnetic layer 15 is about 15 nm. The pinned layer 16 is formed of, for example, Ni₈₀Fe₂₀, and the thickness of the pinned layer 16 is about 3 nm. The gap layer 17 is formed of, for example, Cu, and the thickness of the gap layer 17 is about 3 nm. The free layer 18 is formed of, for example, Ni₈₀Fe₂₀, and the thickness of the free layer 18 is about 6 nm. The magnetization direction of the pinned layer 16 is fixed, and the antiferromegnetic layer 15 is for fixing the magnetization direction of the pinned layer 16. The magnetization direction of the free layer 18 is not fixed.

The giant magnetoresistive thin film 2 having the above-mentioned laminated structure and thicknesses is grown by a sequential sputtering deposition method. The pinned layer 16 and the free layer 18 may be formed of Co₈₀Fe₂₀, instead of Ni₈₀Fe₂₀. FIG. 1A is a plan view illustrating the free layer 18, and FIG. 1B is a cross-sectional view illustrating the pinned layer 16 and the free layer 18 of the giant magnetoresistive thin film 2. In the giant magnetoresistive thin film 2, the layers may be laminated in a different order from the above, for example, in the order of the seed layer, the free layer, the gap layer, the pinned layer, the antiferromegnetic layer, and the protective layer, if necessary.

A magnetoresistive element shown in the following drawings is formed in a desired shape by etching the giant magnetoresistive thin film 2. In the following drawings, as shown in FIG. 1B, the magnetoresistive element is schematically illustrated to include the pinned layer 16 and the free layer 18. Arrows shown in the pinned layer 16 and the free layer 18 in FIGS. 1B and 1C indicate the degree of magnetization. Meanwhile, the magnetoresistive element may be formed using, for example, an anisotropic magnetoresistive thin film, a spin valve thin film, or a tunnel-type magnetoresistive thin film other than the giant magnetoresistive thin film 2.

### First Embodiment

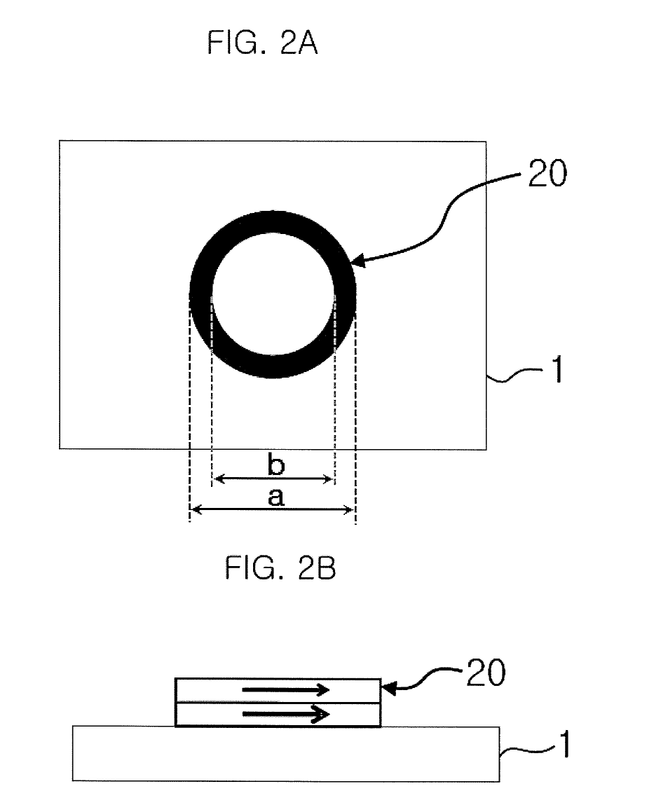

FIGS. 2A to 8B are diagrams sequentially illustrating the structure of a magnetic field detector according to a first embodiment of the invention and a method of manufacturing the same. The magnetic field detector according to the first embodiment is characterized in that it includes a magnetoresistive element with a single circular ring shape.

First, the giant magnetoresistive thin film 2 is formed on the substrate 1 by vapor deposition and then etched to form a magnetoresistive element 20 with a circular ring shape (see FIGS. 2A and 2B). In the etching process, dry etching, such as an Ar gas ion milling method, is performed on the giant magnetoresistive thin film 2 shown in FIG. 1C to etch all the portions of the film except a circular ring portion. FIG. 2A is a plan view, and FIG. 2B is a diagram illustrating the arrangement of the substrate 1 and the magnetoresistive element 20. For example, in the first embodiment, the magnetoresistive element 20 has an outside diameter a of about 100 nm to 30 μm, and the magnetoresistive element 20 has a width b of about 100 nm to 5 μm. The dimensions of the magnetoresistive element 20 may be applied to the following other embodiments. Of course, the dimensions of the magnetoresistive element 20 are just illustrative, but the invention is not limited thereto.

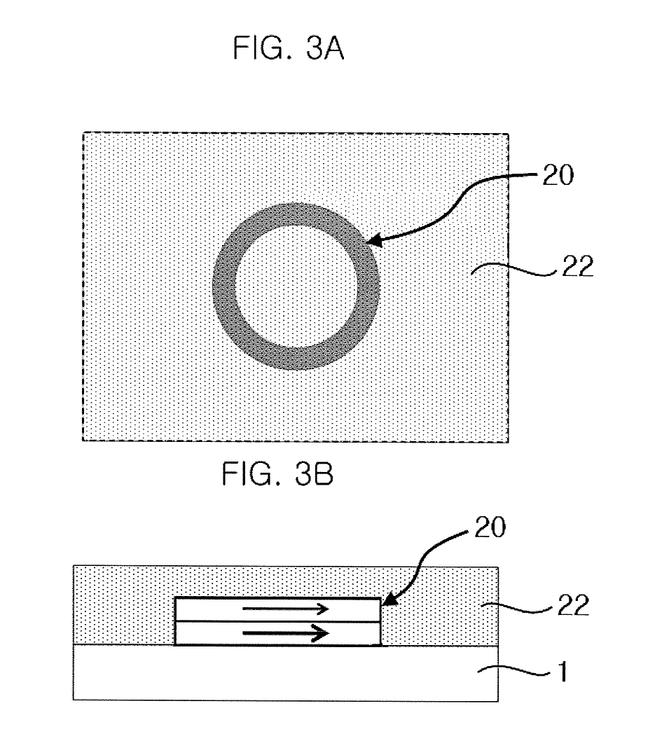

As shown in FIGS. 3A and 3B, a metal thin film layer 22 formed of Au is deposited on the substrate 1 and the magnetoresistive element 20. For example, Au is grown with a thickness of about 150 nm by a sputtering deposition method under the conditions of an argon gas pressure of about 3×10⁻⁴ Torr, a sputtering power of about 60 W, and room temperature, thereby forming the metal thin film layer 22. FIG. 3A is a plan view, and FIG. 3B is a diagram illustrating the deposited metal thin film layer 22. The metal thin film layer 22 may be formed of Ta.

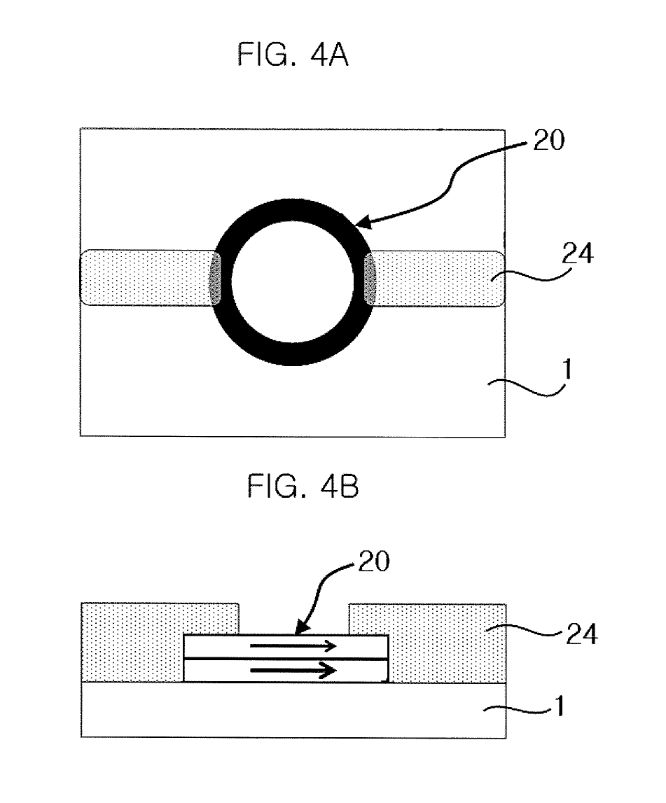

As shown in FIGS. 4A and 4B, electrode pads 24 are formed. The electrode pads 24 are used as electrodes for applying a current and measuring a horizontal voltage. The electrode pads 24 are formed by a lift-up method, using dry etching or a negative photosensitive mask. In this case, all the portions of the metal thin film layer 22 except for portions serving as the electrode pads 24 are removed. For example, the electrode pads 24 are formed on the left and right of the magnetoresistive element 20 so as to face each other in the horizontal direction. FIG. 4A is a plan view, and FIG. 4B is a diagram illustrating the formed electrode pads 24.

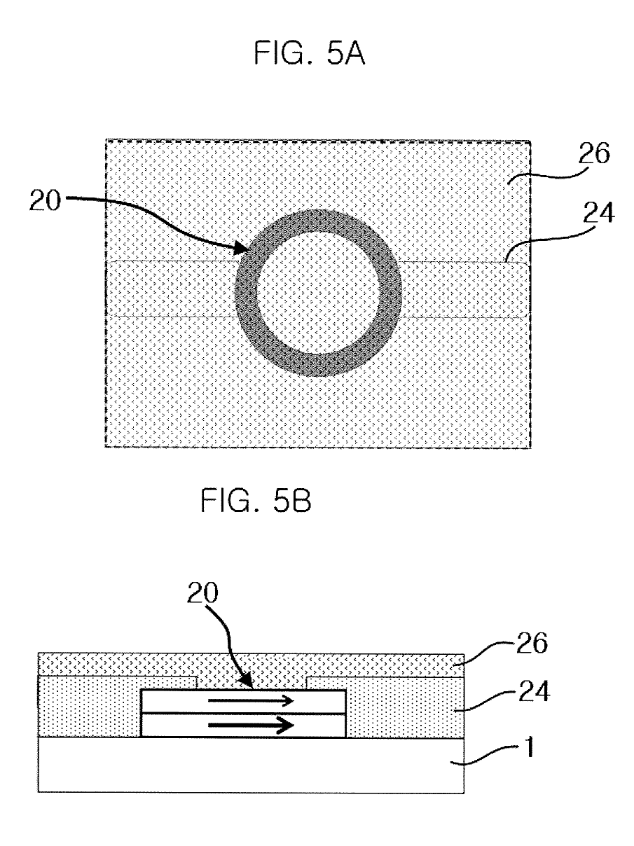

As shown in FIGS. 5A and 5B, an insulating thin film layer 26 is deposited on the substrate 1, the magnetoresistive element 20, and the electrode pads 24. The insulating thin film layer 26 is formed of SiO₂ or Si₃N₄. In order to prevent the magnetoresistive element 20 and the electrode pads 24 from corroded by an analytical solution, for example, SiO₂ or Si₃N₄ is grown with a thickness of about 50 to 300 nm (preferably, 150 nm) by a sputtering deposition method under the conditions of an argon gas pressure of about 3×10⁻⁴ Torr, a sputtering power of about 100 W, and room temperature, thereby forming the SiO₂ or Si₃N₄ insulating thin film layer 26. FIG. 5A is a plan view, and FIG. 5B is a diagram illustrating the formed insulating thin film layer 26.

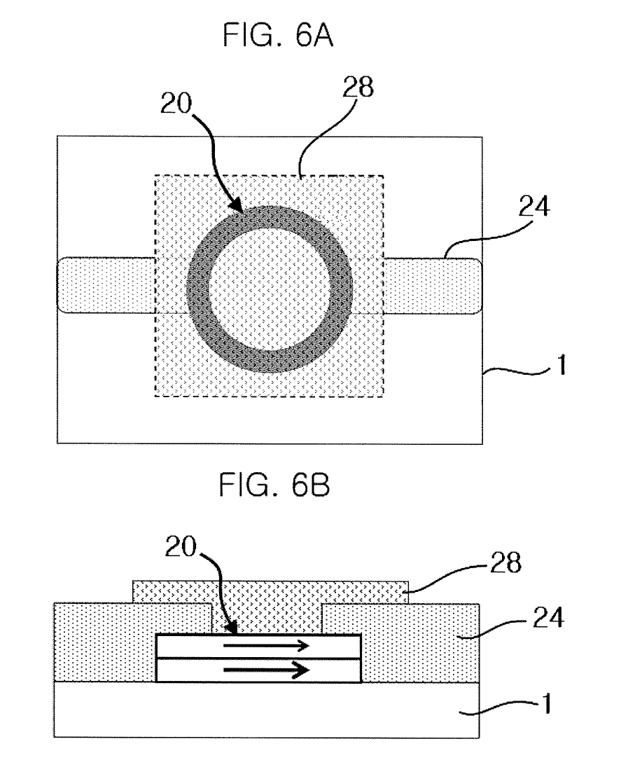

As shown in FIGS. 6A and 6B, the insulating thin film layer 26 is partially removed to form an insulating protective layer 28. All the portions of the insulating thin film layer 26 except a portion serving as the insulating protective layer are removed by a lift-up method, using dry etching, such as an Ar gas ion milling method, or a negative photosensitive mask, thereby forming the insulating protective layer 28. FIG. 6A is a plan view, and FIG. 6B is a diagram illustrating the formed insulating protective layer 28.

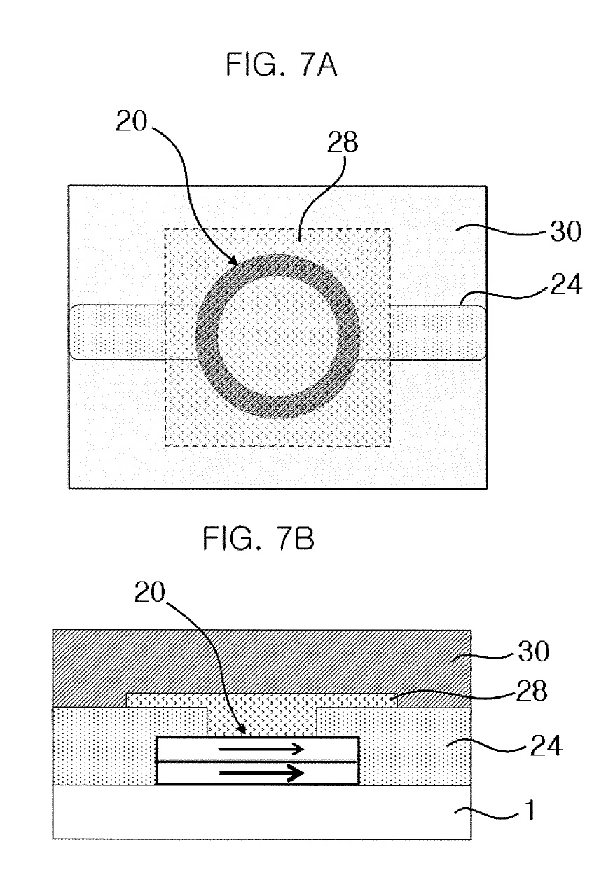

As shown in FIGS. 7A and 7B, a photosensitive magnetic bead thin film 30 is deposited on the substrate 1, the electrode pads 24, and the insulating protective layer 28. The photosensitive magnetic bead thin film 30 is formed with a thickness of about 1 to 2 μm (preferably, about 1.5 μm) at room temperature by spin coating at a speed of about 3000 to 5000 rpm. FIG. 7A is a plan view, and FIG. 7B is a diagram illustrating the deposited photosensitive magnetic bead thin film 30.

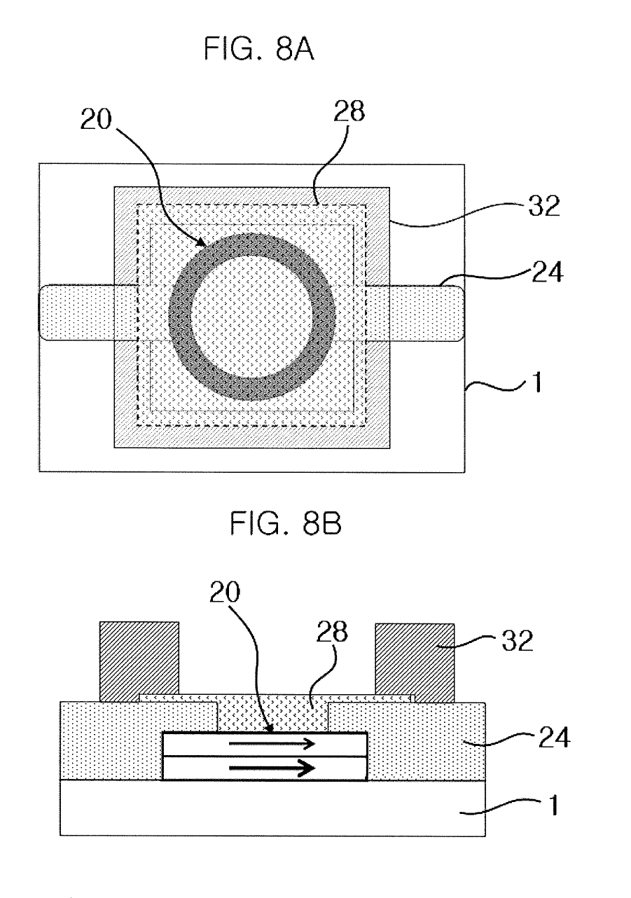

As shown in FIGS. 8A and 8B, the photosensitive magnetic bead thin film 30 is selectively removed to form a magnetic bead limiting layer 32. The magnetic bead limiting layer 32 is formed by removing all the portions of the photosensitive magnetic bead thin film 30 except a portion serving as the magnetic bead limiting layer 32, using a lift-up method and a negative photosensitive mask. The magnetic bead limiting layer 32 can impound a magnetic bead analytical solution therein such that the magnetic bead analytical solution is positioned close to the magnetoresistive element 20. That is, since the magnetic bead limiting layer 32 impounds an analytical solution containing magnetic beads in a predetermined are, it is possible to minimize the stray field. FIG. 8A is a plan view and FIG. 8B is a diagram illustrating the formed magnetic bead limiting layer 32.

The magnetic field detector manufactured through the above-mentioned processes includes the magnetoresistive element 20 with a circular ring shape that is grown on the Si single crystal substrate 1, and the electrodes 24 for applying a current to the magnetoresistive element 20 and measuring a horizontal voltage, as shown in FIGS. 8A and 8B. The insulating protective layer 28 is deposited on the entire surface of the magnetoresistive element 20 and portions of the electrodes 24, and the magnetic bead limiting layer 32 is formed on the magnetoresistive element 20, the electrodes 24, and the insulating protective layer 28. The electrodes 24 mean the electrode pads described with reference to FIGS. 4A and 4B, and may be called horizontal electrodes.

In the magnetic field detector according to the first embodiment, since a stray field is formed inside the magnetoresistive element having a circular ring shape, the stray field is circulated in the magnetoresistive element, and does not leak to the outside of the element. As a result, there is no mutual interference due to the stray field.

When the magnetic bead is magnetized by a magnetic field applied from the outside, a weak magnetic field is generated, and the generated magnetic field has an effect on the magnetization direction of the free layer, which causes a variation in the output voltage of the magnetoresistive element. The variation in the output voltage makes it possible to detect the magnetic bead.

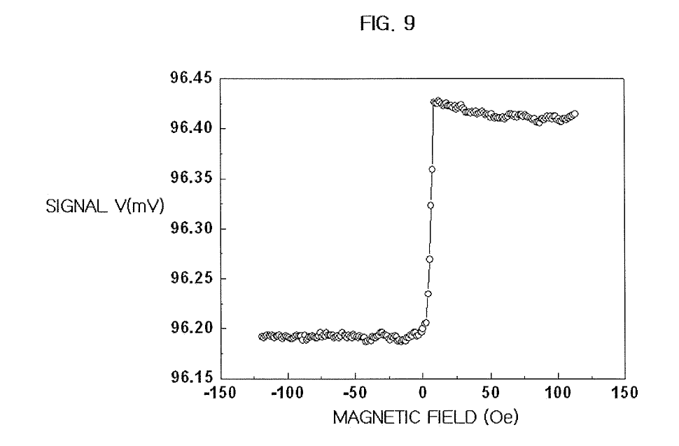

FIG. 9 is a graph illustrating the relationship between a voltage and a magnetic field applied to the magnetic field detector provided with the magnetoresistive element having a circular ring shape. As can be seen from FIG. 9, a rapid voltage variation occurs when the strength of the external magnetic field is around 0 (zero) oersted (Oe). These results prove that the magnetic field detector manufactured by the above-mentioned manufacturing method can detect a very weak magnetic field.

### Second Embodiment

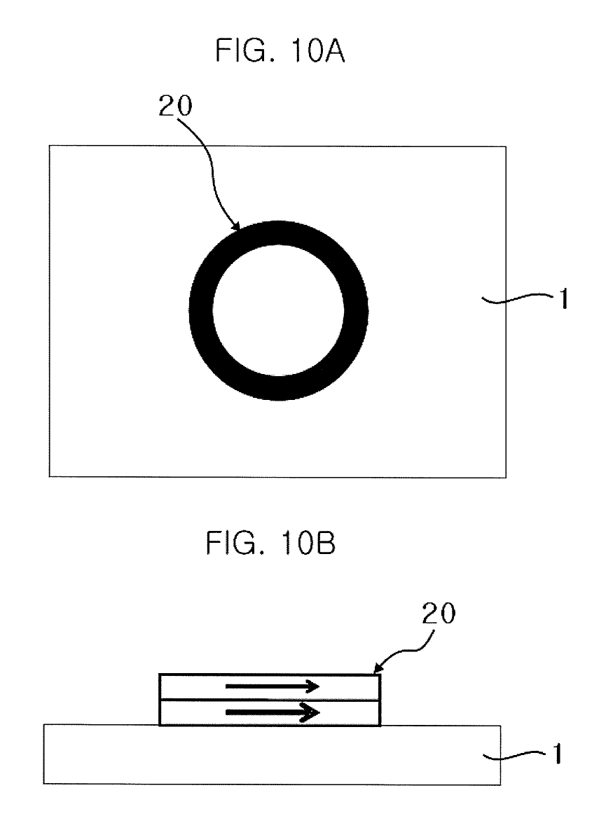

FIGS. 10A to 16B are diagrams sequentially illustrating the structure of a magnetic field detector according to a second embodiment of the invention and a method of manufacturing the same. The magnetic field detector according to the second embodiment differs from the magnetic field detector according to the first embodiment in that it further includes vertical electrodes (vertical electrode pads).

First, a giant magnetoresistive thin film 2 is formed on a substrate 1 by vapor deposition and then etched to form a magnetoresistive element 20 with a circular ring shape (see FIGS. 10A and 10B). In the etching process, dry etching, such as an Ar gas ion milling method, is performed on the giant magnetoresistive thin film 2 shown in FIG. 1C to etch all the portions of the film except a circular ring portion. FIG. 10A is a plan view, and FIG. 10B is a diagram illustrating the arrangement of the substrate 1 and the magnetoresistive element 20.

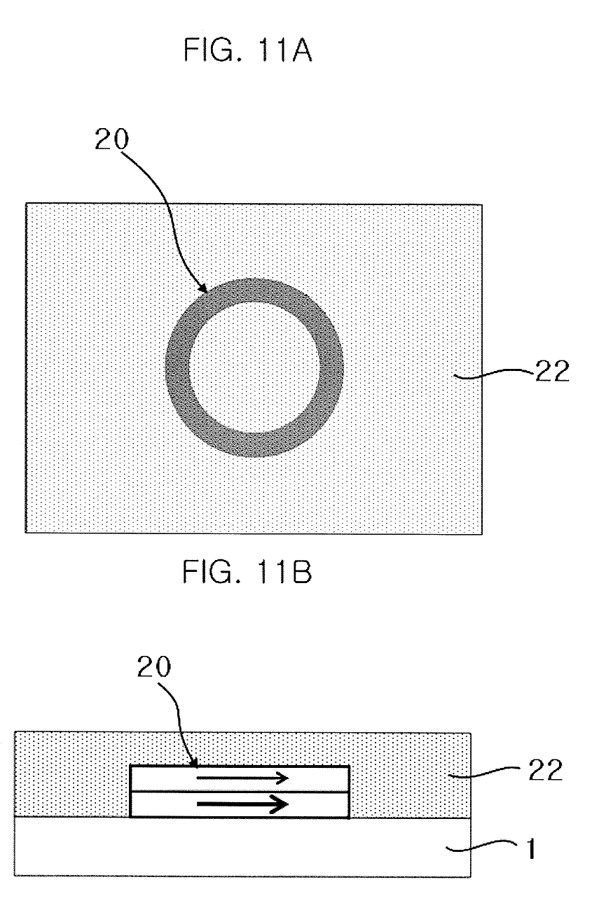

As shown in FIGS. 11A and 11B, a metal thin film layer 22 formed of Au is deposited on the substrate 1 and the magnetoresistive element 20. For example, Au is grown with a thickness of about 150 nm by a sputtering deposition method under the conditions of an argon gas pressure of about 3×10⁻⁴ Torr, a sputtering power of about 60 W, and room temperature, thereby forming the metal thin film layer 22. FIG. 11A is a plan view, and FIG. 11B is a diagram illustrating the deposited metal thin film layer 22. The metal thin film layer 22 may be formed of Ta.

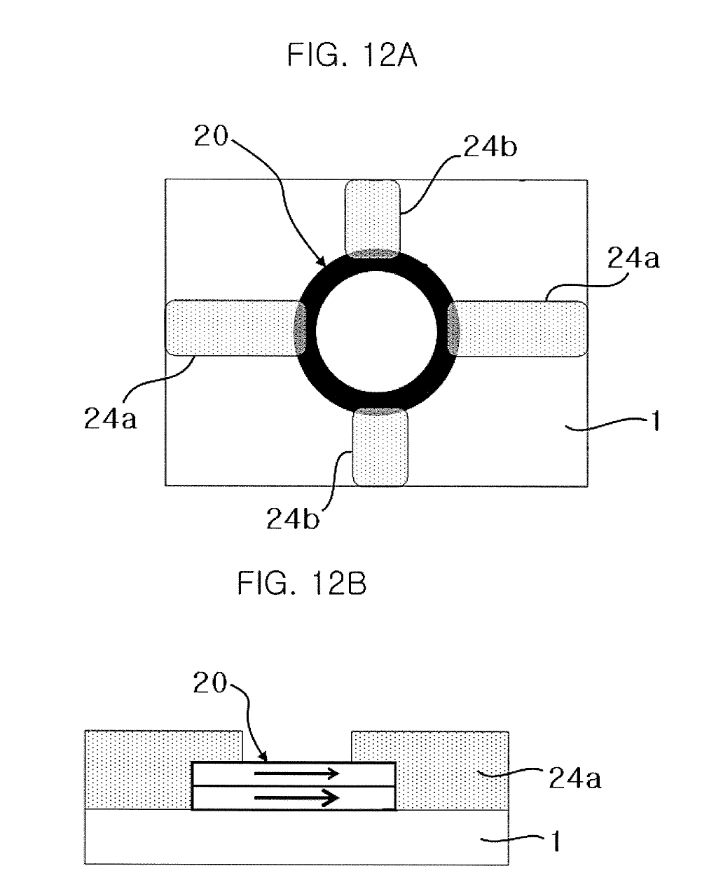

As shown in FIGS. 12A and 12B, horizontal electrode pads 24a and vertical electrode pads 24b are formed. The horizontal electrode pads 24a are used as electrodes for applying a current and measuring a horizontal voltage. The vertical electrode pads 24b are used as electrodes for measuring an output voltage (that is, a vertical voltage) in a direction orthogonal to the direction in which a current flows to the magnetoresistive element 20. The horizontal and vertical electrode pads 24a and 24b are formed by a lift-up method, using dry etching or a negative photosensitive mask. In this case, all the portions of the metal thin film layer 22 except for portions serving as the electrode pads 24a and 24b are selectively removed. For example, the horizontal electrode pads 24a are formed in the horizontal direction so as to face each other with the magnetoresistive element 20 interposed therebetween (that is, so as to be positioned on the left and right of the magnetoresistive element 20). The vertical electrode pads 24b are formed in the vertical direction so as to face each other with the magnetoresistive element 20 interposed therebetween (that is, so as to be positioned on the upper and lower sides of the magnetoresistive element 20). That is, a line lining the horizontal electrode pads 24a in the horizontal direction is orthogonal to a line linking the vertical electrode pads 24b in the vertical direction. FIG. 12A is a plan view, and FIG. 12B is a diagram illustrating the formed electrode pads 24a and 24b.

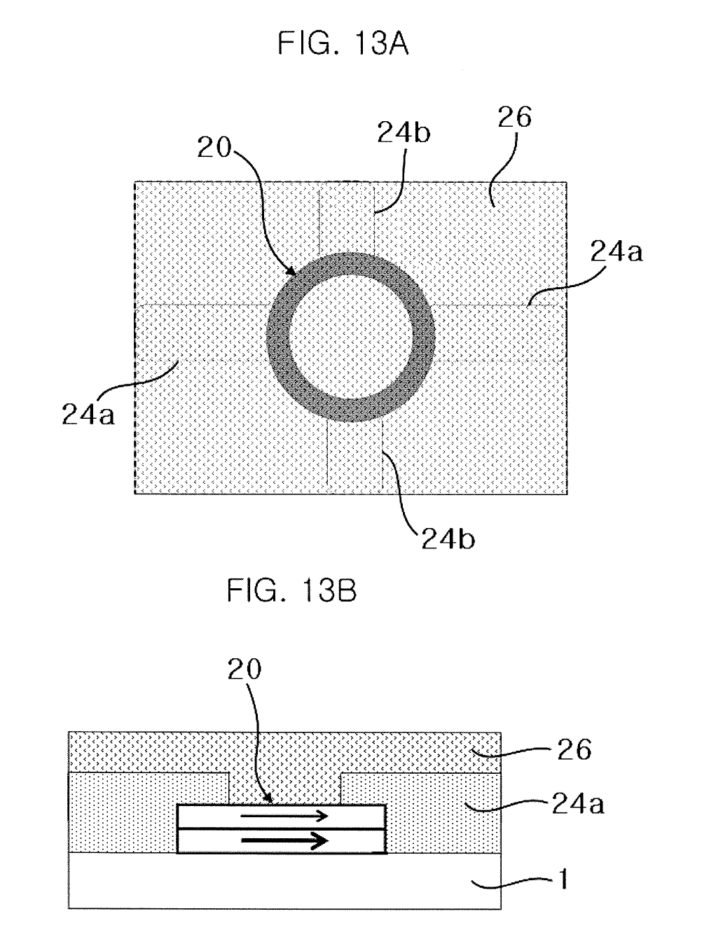

As shown in FIGS. 13A and 13B, an insulating thin film layer 26 is deposited on the substrate 1, the magnetoresistive element 20, and the electrode pads 24a and 24b. The insulating thin film layer 26 is formed of SiO₂ or Si₃N₄. In order to prevent the magnetoresistive element 20 and the electrode pads 24a and 24b from being corroded by an analytical solution, for example, SiO₂ or Si₃N₄ is grown with a thickness of about 50 to 300 nm (preferably, 150 nm) by a sputtering deposition method under the conditions of an argon gas pressure of about 3×10⁻⁴ Torr, a sputtering power of about 100 W, and room temperature, thereby forming the SiO₂ or Si₃N₄ insulating thin film layer 26. FIG. 13A is a plan view, and FIG. 13B is a diagram illustrating the formed insulating thin film layer 26.

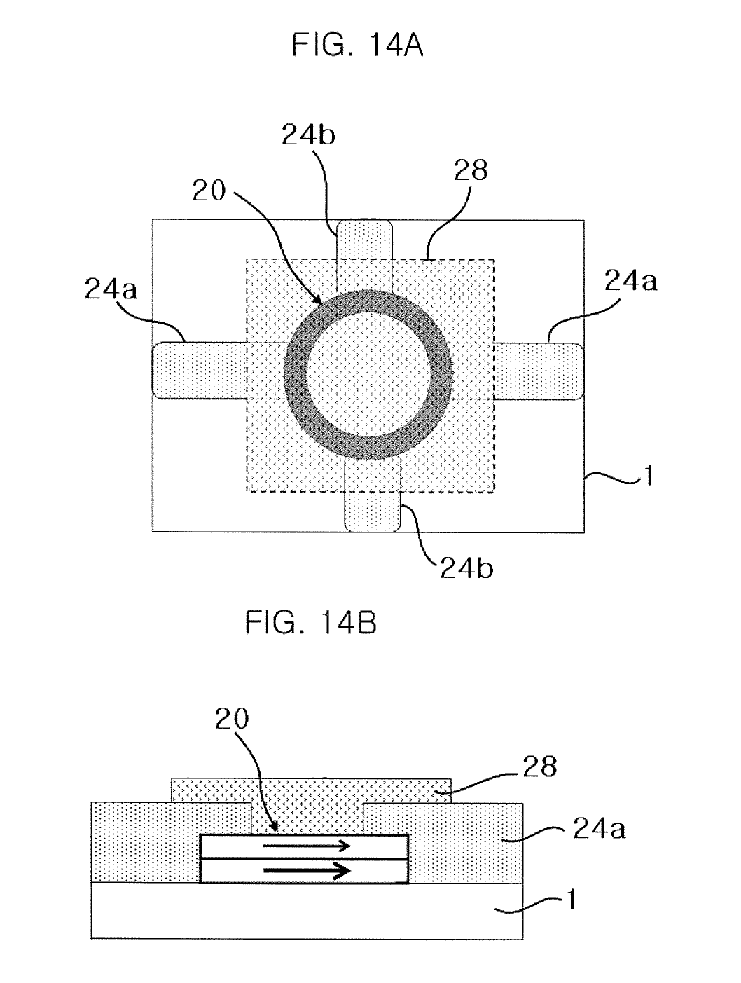

As shown in FIGS. 14A and 14B, the insulating thin film layer 26 is partially removed to form an insulating protective layer 28. All the portions of the insulating thin film layer 26 except a portion serving as the insulating protective layer are removed by a lift-up method, using dry etching, such as an Ar gas ion milling method, or a negative photosensitive mask, thereby forming the insulating protective layer 28. The insulating protective layer 28 covers the entire surface of the magnetoresistive element 20 and portions of the horizontal and vertical electrode pads 24a and 24b. FIG. 14A is a plan view, and FIG. 14B is a diagram illustrating the formed insulating protective layer 28.

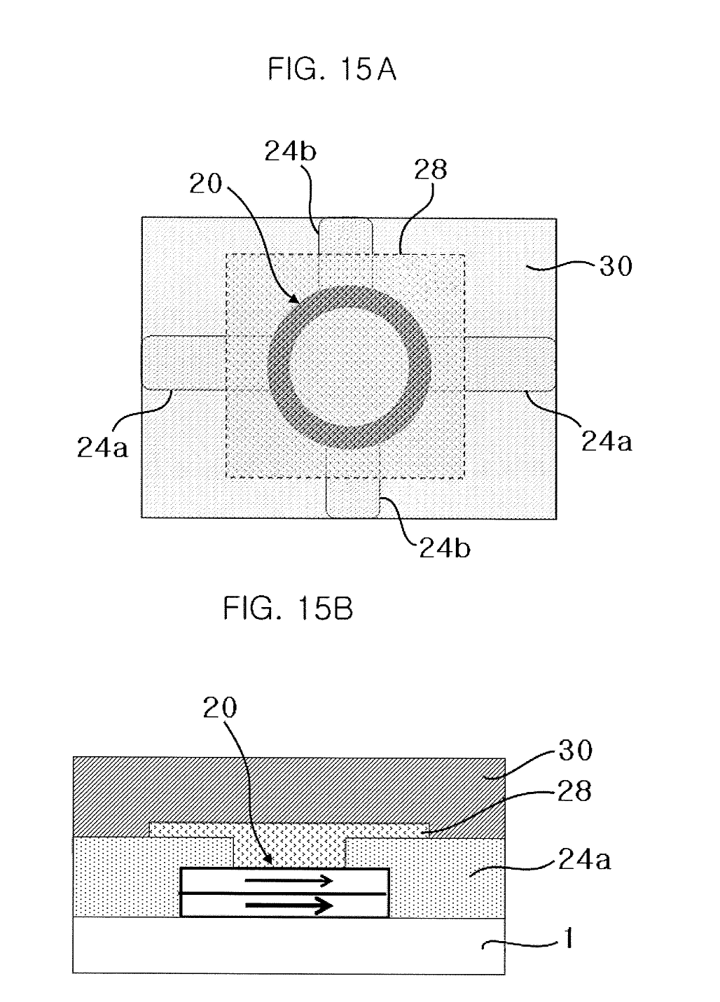

As shown in FIGS. 15A and 15B, a photosensitive magnetic bead thin film 30 is deposited on the substrate 1, the electrode pads 24a and 24b, and the insulating protective layer 28. The photosensitive magnetic bead thin film 30 is formed with a thickness of about 1 to 2 μm (preferably, about 1.5 μm) at room temperature by spin coating at a speed of about 3000 to 5000 rpm. FIG. 15A is a plan view, and FIG. 15B is a diagram illustrating the deposited photosensitive magnetic bead thin film 30.

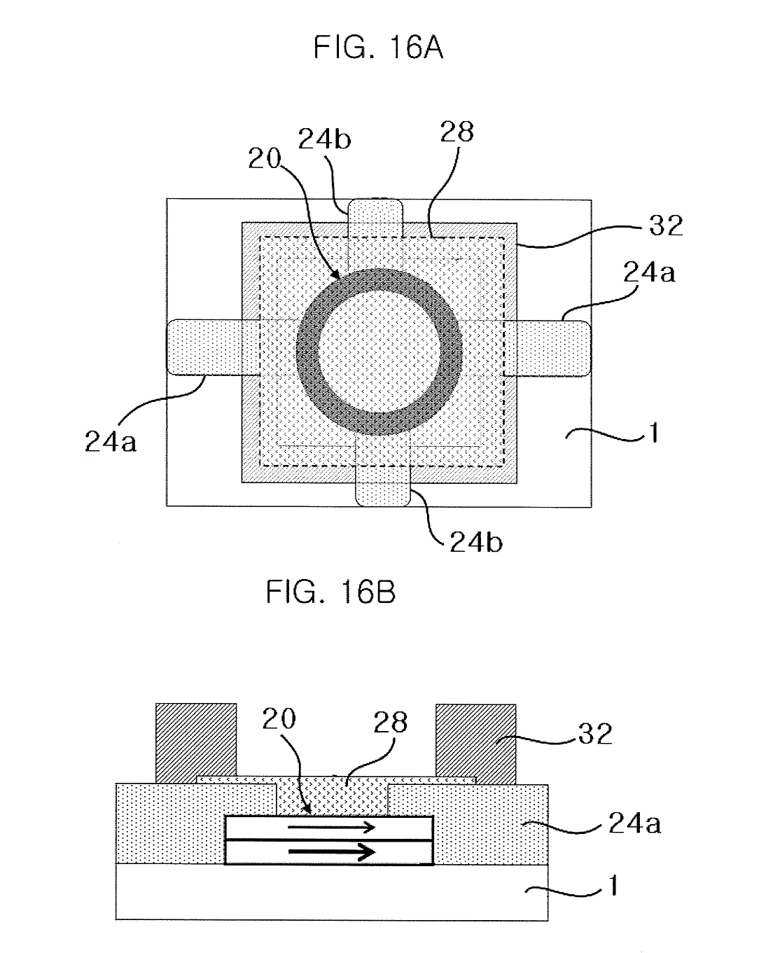

As shown in FIGS. 16A and 16B, the photosensitive magnetic bead thin film 30 is selectively removed to form a magnetic bead limiting layer 32. The magnetic bead limiting layer 32 is formed by removing all the portions of the photosensitive magnetic bead thin film 30 except a portion serving as the magnetic bead limiting layer 32, using a lift-up method and a negative photosensitive mask. The magnetic bead limiting layer 32 can impound a magnetic bead analytical solution therein such that the magnetic bead analytical solution is positioned close to the magnetoresistive element 20. FIG. 16A is a plan view and FIG. 16B is a diagram illustrating the formed magnetic bead limiting layer 32.

The magnetic field detector manufactured through the above-mentioned processes includes the magnetoresistive element 20 with a circular ring shape that is grown on the Si single crystal substrate 1, the horizontal electrodes 24a for applying a current to the magnetoresistive element 20 and measuring a horizontal voltage, and the vertical electrodes 24b for measuring a vertical voltage, as shown in FIGS. 16A and 16B. The insulating protective layer 28 is deposited on the entire surface of the magnetoresistive element 20 and portions of the electrodes 24a and 24b, and the magnetic bead limiting layer 32 is formed on the magnetoresistive element 20, the electrodes 24a and 24b, and the insulating protective layer 28. The horizontal electrodes 24a mean the horizontal electrode pads described with reference to FIGS. 12A and 12B, and the vertical electrodes 24b mean the vertical electrode pads described with reference to FIGS. 12A and 12B.

In the magnetic field detector according to the second embodiment, since a stray field is formed inside the magnetoresistive element having a circular ring shape, the stray field is circulated in the magnetoresistive element, but does not leak to the outside of the element. As a result, there is no mutual interference due to the stray field.

When the magnetic bead is magnetized by a magnetic field applied from the outside, a weak magnetic field is generated, and the generated magnetic field has an effect on the magnetization direction of the free layer, which causes a variation in the output voltage of the magnetoresistive element. As a result, the variation in the output voltage makes it possible to detect the magnetic bead.

### Third Embodiment

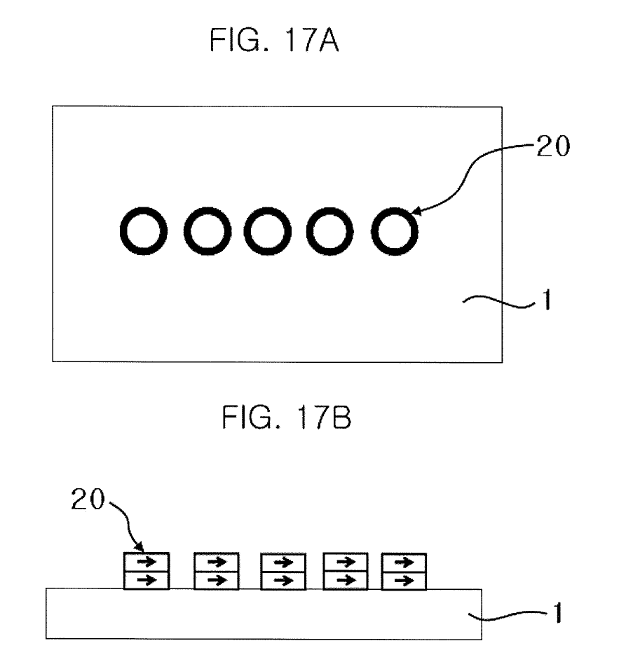

FIGS. 17A to 23B are diagrams sequentially illustrating the structure of a magnetic field detector according to a third embodiment of the invention and a method of manufacturing the same. The third embodiment differs from the first embodiment in that a plurality of magnetoresistive elements having circular ring shapes (that is, a one-dimensional array structure) are arranged in a line. Since the manufacturing method according to the third embodiment is most similar to that according to the first embodiment, those skilled in the art can easily understand the manufacturing method according to the third embodiment.

First, a giant magnetoresistive thin film 2 is formed on a substrate 1 by vapor deposition and then etched to form an array of a plurality of magnetoresistive elements 20 with circular ring shapes (see FIGS. 17A and 17B). The plurality of magnetoresistive elements 20 are arrayed in a line at equal distances. In the etching process, dry etching, such as an Ar gas ion milling method, is performed on the giant magnetoresistive thin film 2 shown in FIG. 1C to etch all the portions of the film except circular ring portions. FIG. 17A is a plan view, and FIG. 17B is a diagram illustrating the arrangement of the substrate 1 and the plurality of magnetoresistive elements 20.

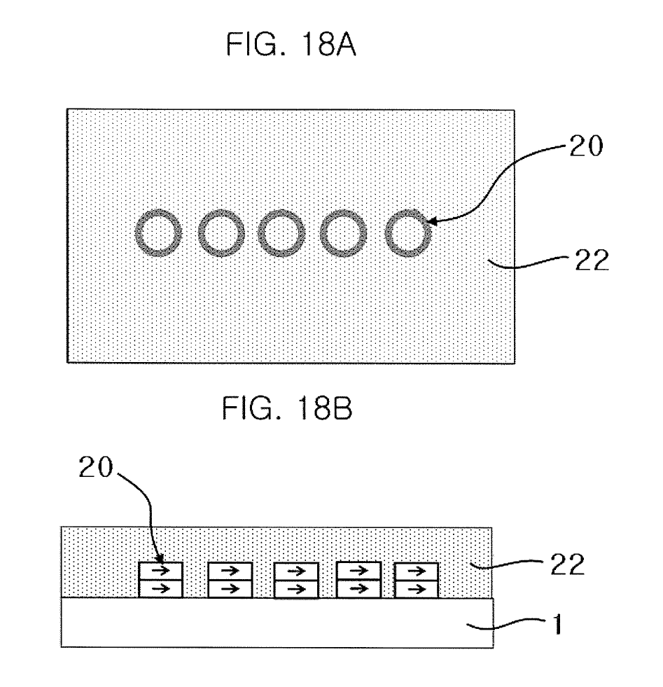

As shown in FIGS. 18A and 18B, a metal thin film layer 22 formed of Au is deposited on the substrate 1 and the plurality of magnetoresistive elements 20. For example, Au is grown with a thickness of about 150 nm by a sputtering deposition method under the conditions of an argon gas pressure of about 3×10⁻⁴ Torr, a sputtering power of about 60 W, and room temperature, thereby forming the metal thin film layer 22. FIG. 18A is a plan view, and FIG. 18B is a diagram illustrating the deposited metal thin film layer 22. The metal thin film layer 22 may be formed of Ta.

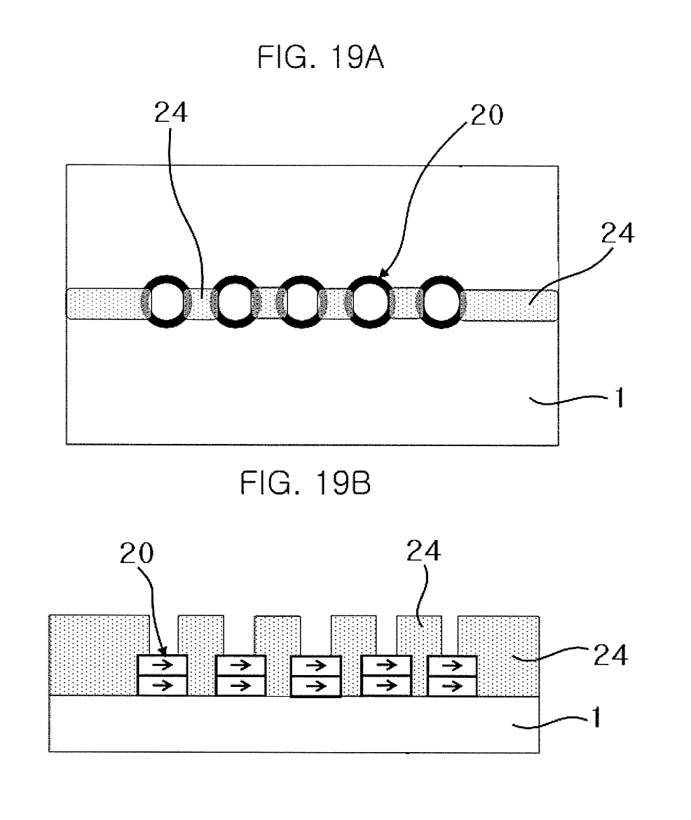

As shown in FIGS. 19A and 19B, electrode pads 24 are formed. The electrode pads 24 are used as electrodes for applying a current and measuring a horizontal voltage. The electrode pads 24 are formed by a lift-up method, using dry etching or a negative photosensitive mask. In this case, all the portions of the metal thin film layer 22 except for portions serving as the electrode pads 24 are removed. For example, the electrode pads 24 include electrode pads connecting the plurality of magnetoresistive elements 20 in the horizontal direction, and electrode pads extending from the rightmost and leftmost magnetoresistive elements 20 to the outside in the horizontal direction. FIG. 19A is a plan view, and FIG. 19B is a diagram illustrating the formed electrode pads 24.

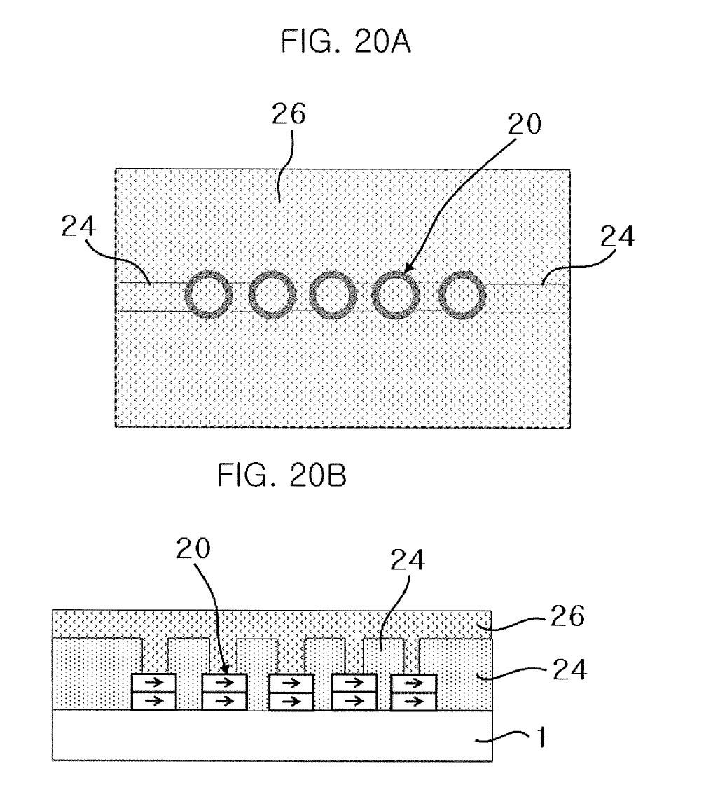

As shown in FIGS. 20A and 20B, an insulating thin film layer 26 is deposited on the substrate 1, the magnetoresistive elements 20, and the electrode pads 24. The insulating thin film layer 26 is formed of SiO₂ or Si₃N₄. In order to prevent the magnetoresistive elements 20 and the electrode pads 24 from corroded by an analytical solution, for example, SiO₂ or Si₃N₄ is grown with a thickness of about 50 to 300 nm (preferably, 150 nm) by a sputtering deposition method under the conditions of an argon gas pressure of about 3×10⁻⁴ Torr, a sputtering power of about 100 W, and room temperature, thereby forming the SiO₂ or Si₃N₄ insulating thin film layer 26. FIG. 20A is a plan view, and FIG. 20B is a diagram illustrating the formed insulating thin film layer 26.

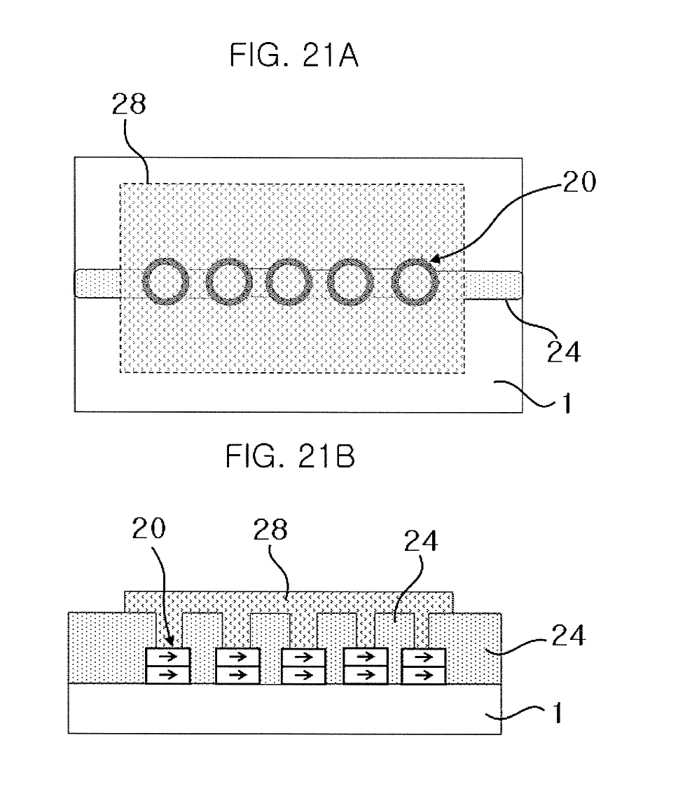

As shown in FIGS. 21A and 21B, the insulating thin film layer 26 is partially removed to form an insulating protective layer 28. All the portions of the insulating thin film layer 26 except a portion serving as the insulating protective layer are removed by a lift-up method, using dry etching, such as an Ar gas ion milling method, or a negative photosensitive mask, thereby forming the insulating protective layer 28. The insulating protective layer 28 covers the entire surface of each of the plurality of magnetoresistive elements 20 and portions of the horizontal electrode pads 24. FIG. 21A is a plan view, and FIG. 21B is a diagram illustrating the formed insulating protective layer 28.

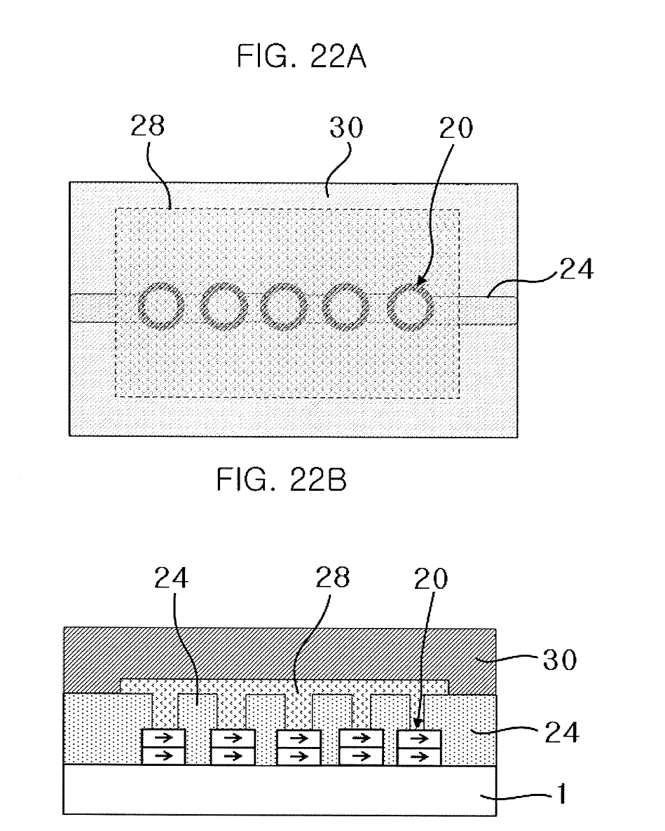

As shown in FIGS. 22A and 22B, a photosensitive magnetic bead thin film 30 is deposited on the substrate 1, the electrode pads 24, and the insulating protective layer 28. The photosensitive magnetic bead thin film 30 is formed with a thickness of about 1 to 2 μm (preferably, about 1.5 μm) at room temperature by spin coating at a speed of about 3000 to 5000 rpm. FIG. 22A is a plan view, and FIG. 22B is a diagram illustrating the deposited photosensitive magnetic bead thin film 30.

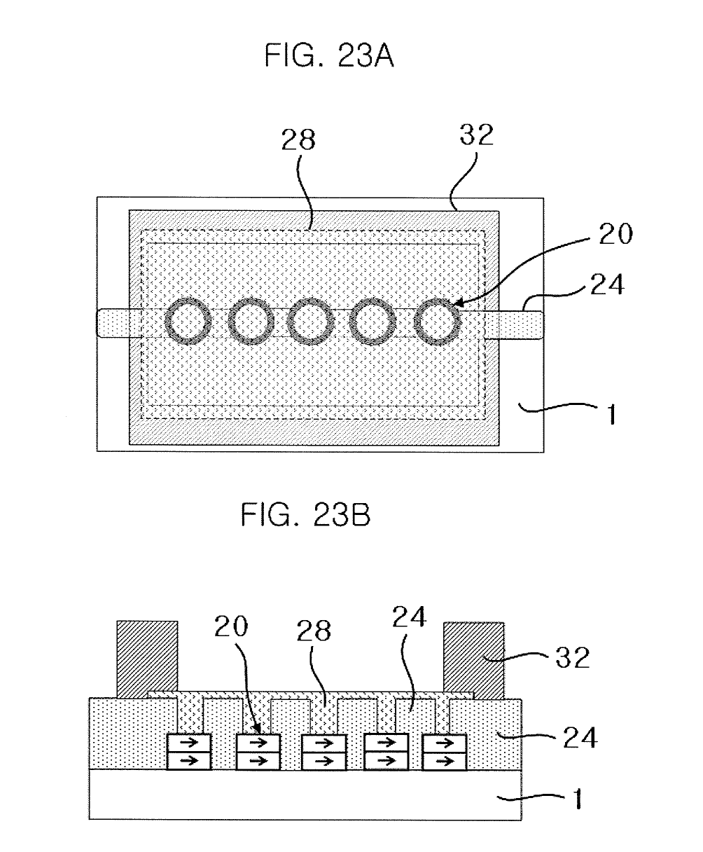

As shown in FIGS. 23A and 23B, the photosensitive magnetic bead thin film 30 is selectively removed to form a magnetic bead limiting layer 32. The magnetic bead limiting layer 32 is formed by removing all the portions of the photosensitive magnetic bead thin film 30 except a portion serving as the magnetic bead limiting layer 32, using a lift-up method and a negative photosensitive mask. The magnetic bead limiting layer 32 can impound a magnetic bead analytical solution therein such that the magnetic bead analytical solution is positioned close to the magnetoresistive element 20. FIG. 23A is a plan view, and FIG. 23B is a diagram illustrating the formed magnetic bead limiting layer 32.

The magnetic field detector manufactured through the above-mentioned processes includes the plurality of magnetoresistive elements 20 with circular ring shapes that are grown on the Si single crystal substrate 1, and the electrodes 24 for applying a current to the plurality of magnetoresistive elements 20 and measuring a horizontal voltage, as shown in FIGS. 23A and 23B. The insulating protective layer 28 is deposited on the entire surface of each of the plurality of magnetoresistive elements 20 and portions of the electrodes 24, and the magnetic bead limiting layer 32 is formed on the plurality of magnetoresistive elements 20, the electrodes 24, and the insulating protective layer 28. The electrodes 24 mean the electrode pads described with reference to FIGS. 19A and 19B, and may be called horizontal electrodes.

In the magnetic field detector according to the third embodiment, since a stray field is formed inside the magnetoresistive element having a circular ring shape, the stray field is circulated in the magnetoresistive element, and does not leak to the outside of the element. As a result, there is no mutual interference due to the stray field.

When the magnetic bead is magnetized by a magnetic field applied from the outside, a weak magnetic field is generated, and the generated magnetic field has an effect on the magnetization direction of the free layer, which causes a variation in the output voltage of the magnetoresistive element. As a result, the variation in the output voltage makes it possible to detect the magnetic bead.

### Fourth Embodiment

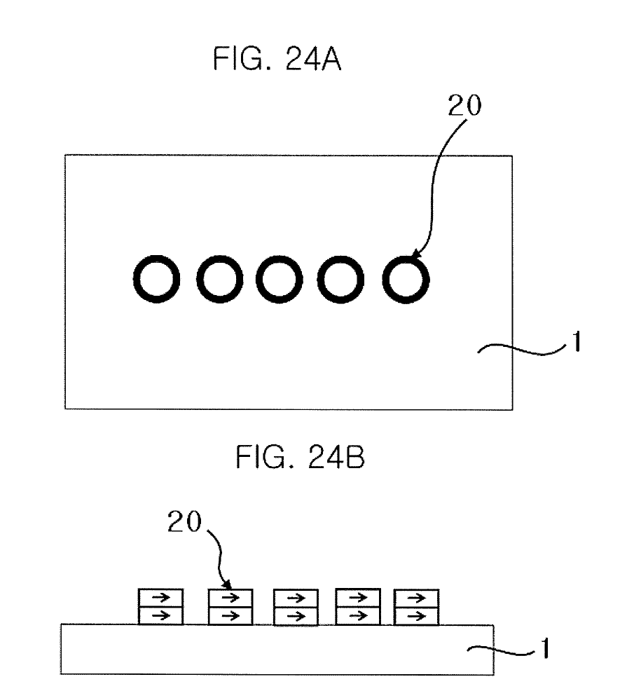

FIGS. 24A to 30B are diagrams sequentially illustrating the structure of a magnetic field detector according to a fourth embodiment of the invention and a method of manufacturing the same. The magnetic field detector according to the fourth embodiment differs from that according to the second embodiment in that a plurality of magnetoresistive elements having circular ring shapes are arranged in a line (that is, a one-dimensional array structure). Since the manufacturing method according to the fourth embodiment is most similar to that according to the second embodiment, those skilled in the art can easily understand the manufacturing method according to the fourth embodiment.

First, a giant magnetoresistive thin film 2 is formed on a substrate 1 by vapor deposition and then etched to form an array of a plurality of magnetoresistive elements 20 with circular ring shapes (see FIGS. 24A and 24B). The plurality of magnetoresistive elements 20 are arrayed in a line at equal distances (that is, a one-dimensional array structure). In the etching process, dry etching, such as an Ar gas ion milling method, is performed on the giant magnetoresistive thin film 2 shown in FIG. 1C to selectively etch all the portions of the film except circular ring portions. FIG. 24A is a plan view, and FIG. 24B is a diagram illustrating the arrangement of the substrate 1 and the plurality of magnetoresistive elements 20.

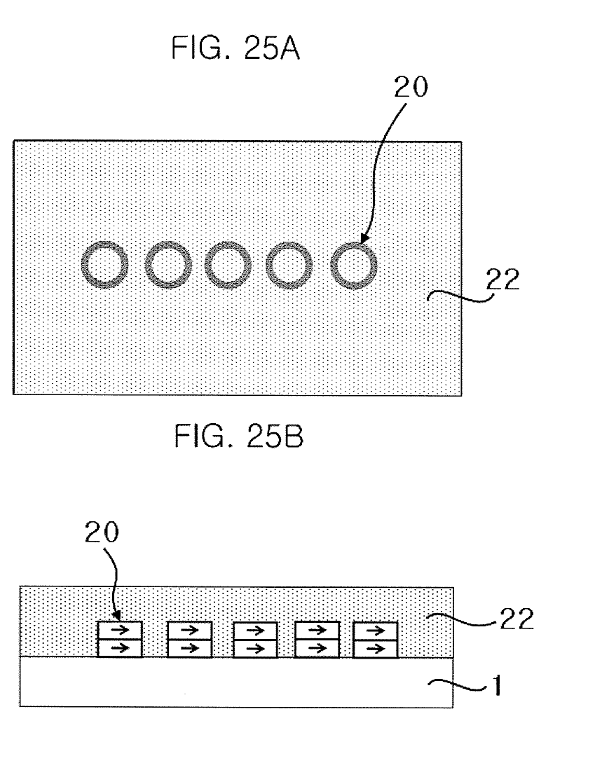

As shown in FIGS. 25A and 25B, a metal thin film layer 22 formed of Au is deposited on the substrate 1 and the plurality of magnetoresistive elements 20. For example, Au is grown with a thickness of about 150 nm by a sputtering deposition method under the conditions of an argon gas pressure of about 3×10⁻⁴ Torr, a sputtering power of about 60 W, and room temperature, thereby forming the metal thin film layer 22. FIG. 25A is a plan view, and FIG. 25B is a diagram illustrating the deposited metal thin film layer 22. The metal thin film layer 22 may be formed of Ta.

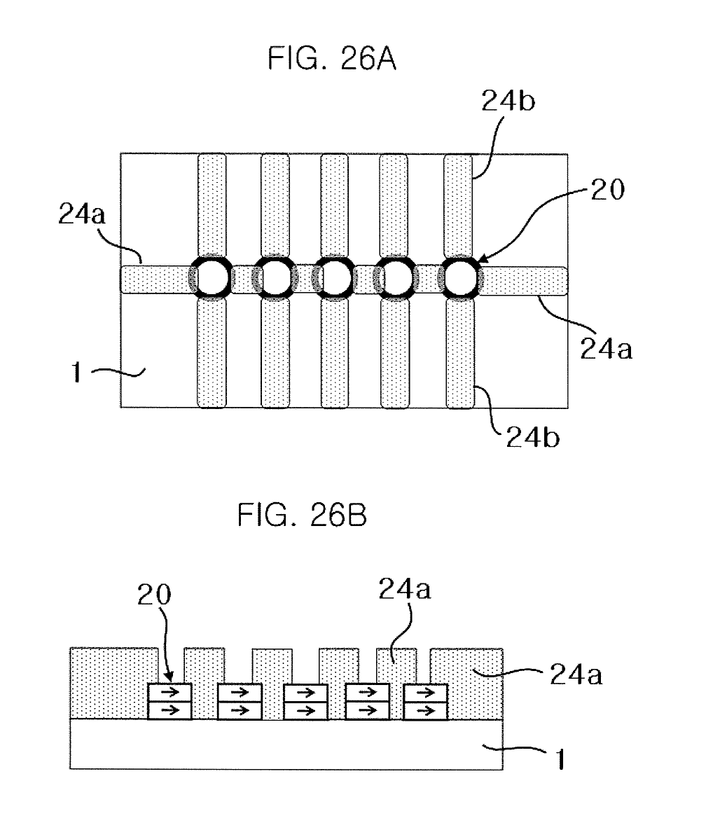

As shown in FIGS. 26A and 26B, horizontal electrode pads 24a and vertical electrode pads 24b are formed. The horizontal electrode pads 24a are used as electrodes for applying a current and measuring a horizontal voltage. The vertical electrode pads 24b are used as electrodes for measuring an output voltage (that is, a vertical voltage) in a direction orthogonal to the direction in which a current flows to the magnetoresistive elements 20. The horizontal and vertical electrode pads 24a and 24b are formed by a lift-up method, using dry etching or a negative photosensitive mask. In this case, all the portions of the metal thin film layer 22 except for portions serving as the electrode pads 24a and 24b are removed. For example, the electrode pads 24a include electrode pads connecting the plurality of magnetoresistive elements 20 in the horizontal direction, and electrode pads extending from the rightmost and leftmost magnetoresistive elements 20 to the outside in the horizontal direction. The vertical electrode pads 24b are formed for each of the magnetoresistive elements 20 so as to be orthogonal to the horizontal electrode pads 24a. That is, a line lining the horizontal electrode pads 24a in the horizontal direction is orthogonal to a line linking the vertical electrode pads 24b in the vertical direction. FIG. 26A is a plan view, and FIG. 26B is a diagram illustrating the formed electrode pads 24a and 24b.

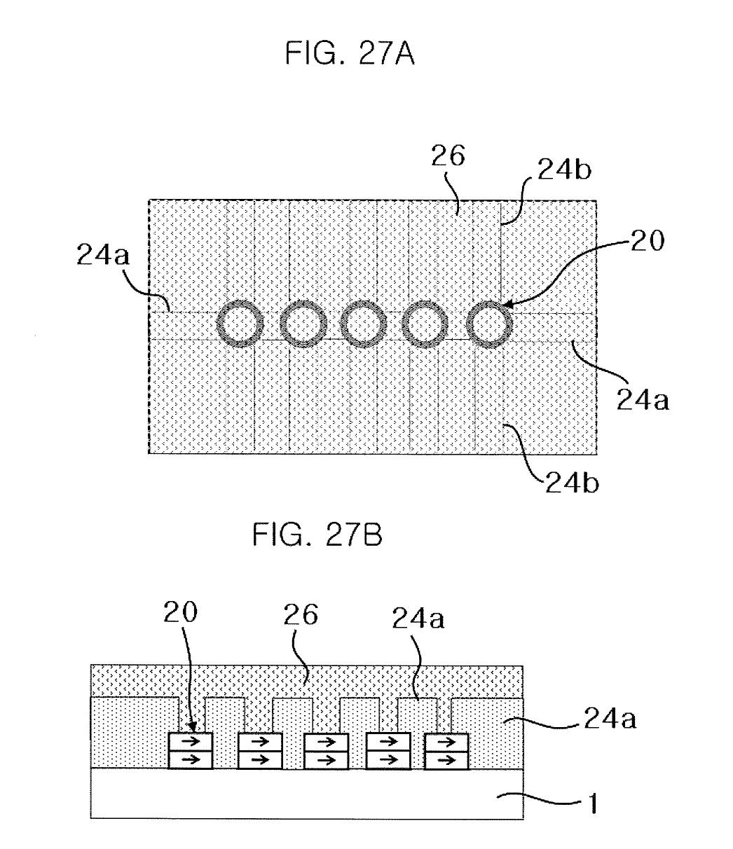

As shown in FIGS. 27A and 27B, an insulating thin film layer 26 is deposited on the substrate 1, the magnetoresistive elements 20, and the electrode pads 24a and 24b. The insulating thin film layer 26 is formed of SiO₂ or Si₃N₄. In order to prevent the magnetoresistive elements 20 and the electrode pads 24a and 24b from being corroded by an analytical solution, for example, SiO₂ or Si₃N₄ is grown with a thickness of about 50 to 300 nm (preferably, 150 nm) by a sputtering deposition method under the conditions of an argon gas pressure of about 3×10⁻⁴ Torr, a sputtering power of about 100 W, and room temperature, thereby forming the SiO₂ or Si₃N₄ insulating thin film layer 26. FIG. 27A is a plan view, and FIG. 27B is a diagram illustrating the formed insulating thin film layer 26.

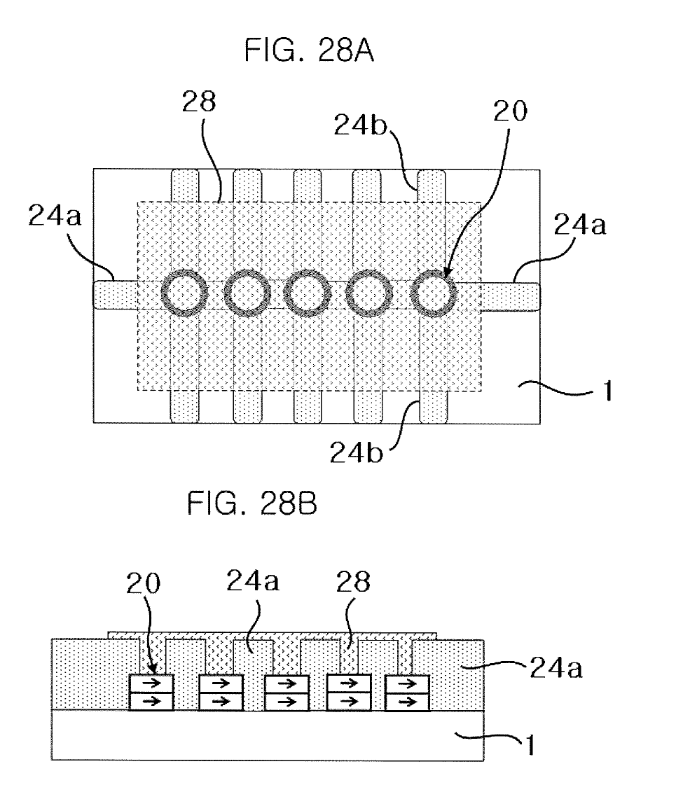

As shown in FIGS. 28A and 28B, the insulating thin film layer 26 is partially removed to form an insulating protective layer 28. All the portions of the insulating thin film layer 26 except a portion serving as the insulating protective layer are removed by a lift-up method, using dry etching, such as an Ar gas ion milling method, or a negative photosensitive mask, thereby forming the insulating protective layer 28. The insulating protective layer 28 covers the entire surface of each of the plurality of magnetoresistive elements 20 and portions of the horizontal and vertical electrode pads 24a and 24b. FIG. 28A is a plan view, and FIG. 28B is a diagram illustrating the formed insulating protective layer 28.

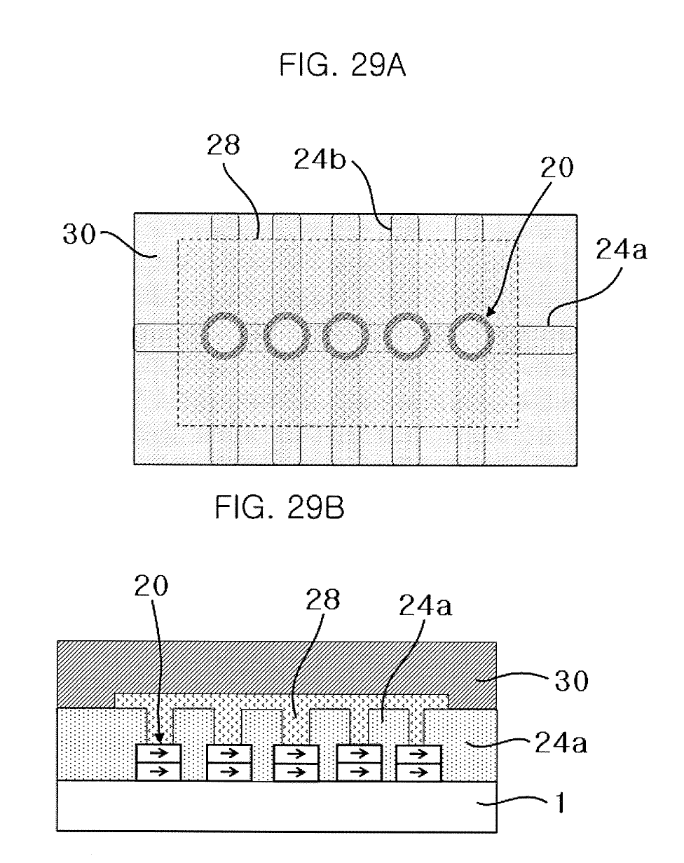

As shown in FIGS. 29A and 29B, a photosensitive magnetic bead thin film 30 is deposited on the substrate 1, the electrode pads 24a and 24b, and the insulating protective layer 28. The photosensitive magnetic bead thin film 30 is formed with a thickness of about 1 to 2 μm (preferably, about 1.5 μm) at room temperature by spin coating at a speed of about 3000 to 5000 rpm. FIG. 29A is a plan view, and FIG. 29B is a diagram illustrating the deposited photosensitive magnetic bead thin film 30.

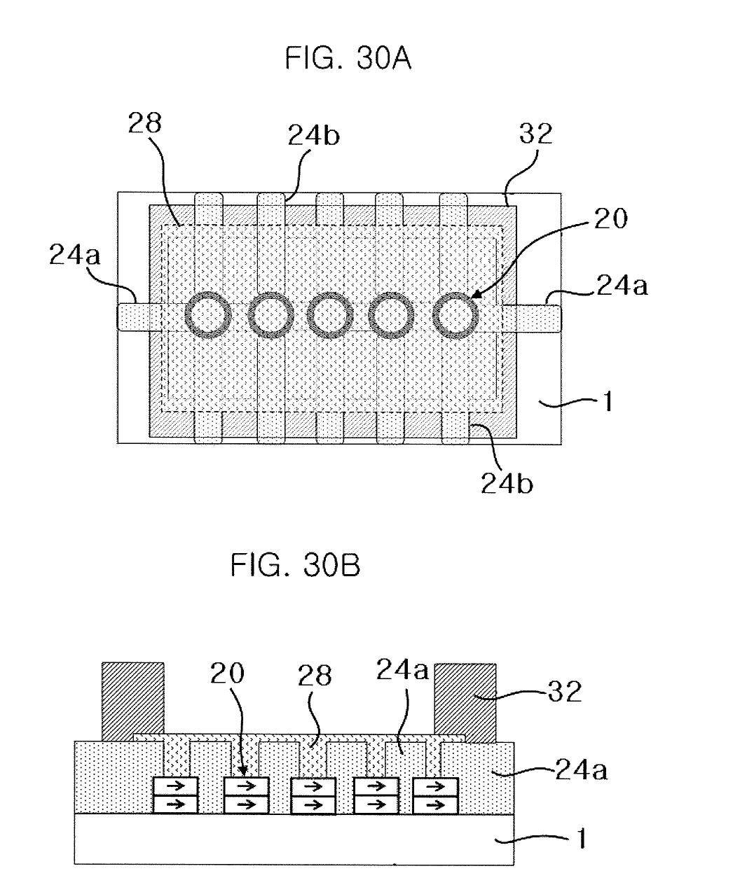

As shown in FIGS. 30A and 30B, the photosensitive magnetic bead thin film 30 is selectively removed to form a magnetic bead limiting layer 32. The magnetic bead limiting layer 32 is formed by removing all the portions of the photosensitive magnetic bead thin film 30 except a portion serving as the magnetic bead limiting layer 32, using a lift-up method and a negative photosensitive mask. The magnetic bead limiting layer 32 can impound a magnetic bead analytical solution therein such that the magnetic bead analytical solution is positioned close to the magnetoresistive element 20. FIG. 30A is a plan view and FIG. 30B is a diagram illustrating the formed magnetic bead limiting layer 32.

The magnetic field detector manufactured through the above-mentioned processes includes the plurality of magnetoresistive elements 20 with circular ring shapes that are grown on the Si single crystal substrate 1, the horizontal electrodes 24a for applying a current to the plurality of magnetoresistive elements 20 and measuring a horizontal voltage, and the vertical electrodes 24b for measuring a vertical voltage, as shown in FIGS. 30A and 30B. The insulating protective layer 28 is deposited on the entire surface of each of the plurality of magnetoresistive elements 20 and portions of the electrodes 24a and 24b, and the magnetic bead limiting layer 32 is formed on the plurality of magnetoresistive elements 20, the electrodes 24a and 24b, and the insulating protective layer 28. The horizontal electrodes 24a mean the horizontal electrode pads described with reference to FIGS. 26A and 26B, and the vertical electrodes 24b mean the vertical electrode pads described with reference to FIGS. 26A and 26B.

In the magnetic field detector according to the fourth embodiment, since a stray field is formed inside the magnetoresistive element having a circular ring shape, the stray field is circulated in the magnetoresistive element, but does not leak to the outside of the element. As a result, there is no mutual interference due to the stray field.

When the magnetic bead is magnetized by a magnetic field applied from the outside, a weak magnetic field is generated, and the generated magnetic field has an effect on the magnetization direction of the free layer, which causes a variation in the output voltage of the magnetoresistive element. As a result, the variation in the output voltage makes it possible to detect the magnetic bead.

### Fifth Embodiment

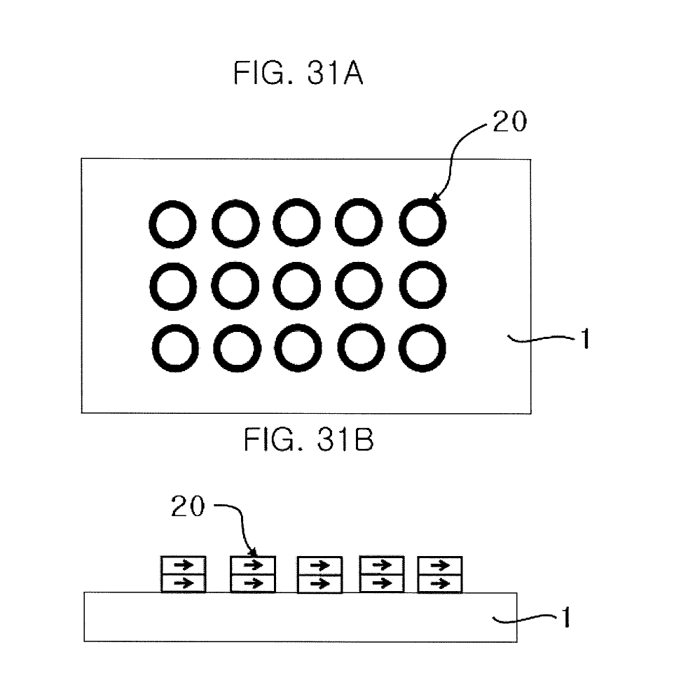

FIGS. 31A to 37B are diagrams sequentially illustrating the structure of a magnetic field detector according to a fifth embodiment of the invention and a method of manufacturing the same. The fifth embodiment differs from the third embodiment in that a plurality of magnetoresistive elements having circular ring shapes are arranged in a two-dimensional array (that is, in a matrix). Since the manufacturing method according to the fifth embodiment is most similar to that according to the third embodiment, those skilled in the art can easily understand the manufacturing method according to the fifth embodiment.

First, a giant magnetoresistive thin film 2 is formed on a substrate 1 by vapor deposition and then etched to form a plurality of magnetoresistive elements 20 with circular ring shapes in a matrix (see FIGS. 31A and 31B). The plurality of magnetoresistive elements 20 are arrayed in a matrix at equal distances. In the etching process, dry etching, such as an Ar gas ion milling method, is performed on the giant magnetoresistive thin film 2 shown in FIG. 1C to etch all the portions of the film except circular ring portions. FIG. 31A is a plan view, and FIG. 31B is a diagram illustrating the arrangement of the substrate 1 and the plurality of magnetoresistive elements 20.

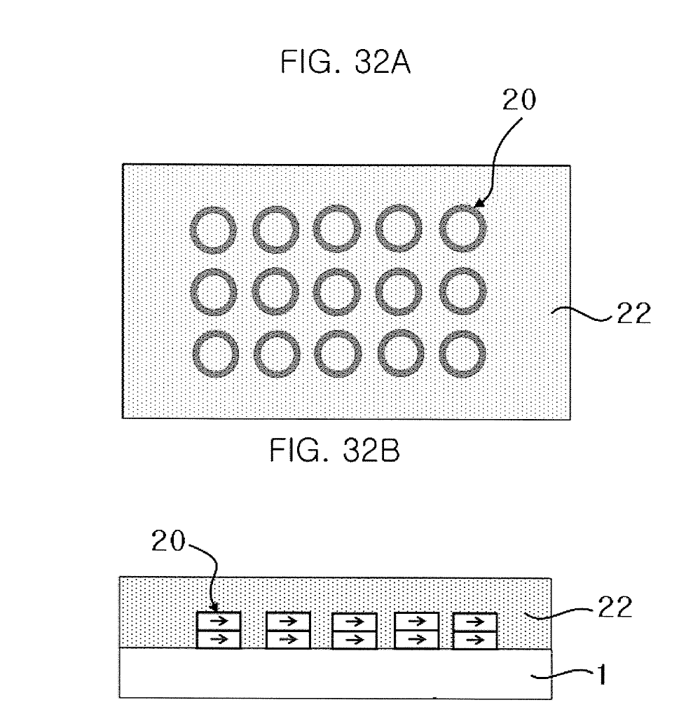

As shown in FIGS. 32A and 32B, a metal thin film layer 22 formed of Au is deposited on the substrate 1 and the plurality of magnetoresistive elements 20. For example, Au is grown with a thickness of about 150 nm by a sputtering deposition method under the conditions of an argon gas pressure of about 3×10⁻⁴ Torr, a sputtering power of about 60 W, and room temperature, thereby forming the metal thin film layer 22. FIG. 32A is a plan view, and FIG. 32B is a diagram illustrating the deposited metal thin film layer 22. The metal thin film layer 22 may be formed of Ta.

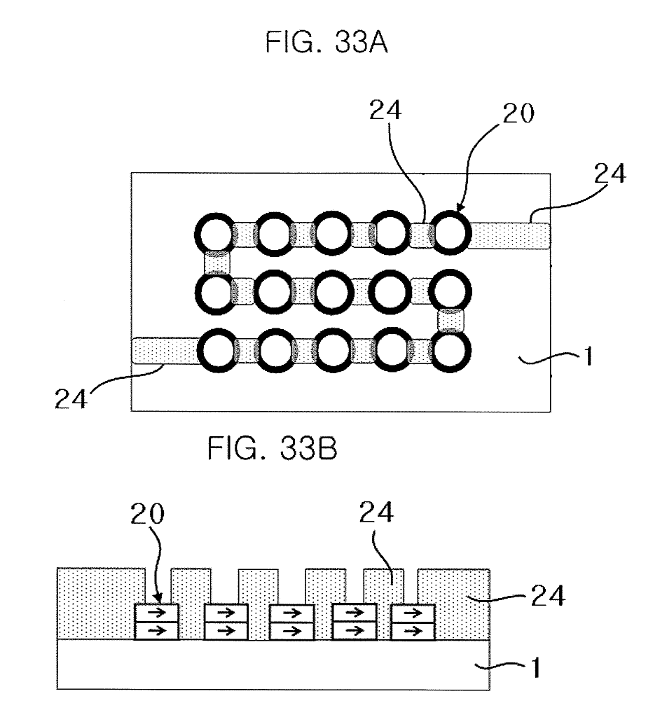

As shown in FIGS. 33A and 33B, electrode pads 24 are formed. The electrode pads 24 are used as electrodes for applying a current and measuring a horizontal voltage. The electrode pads 24 are formed by a lift-up method, using dry etching or a negative photosensitive mask. In this case, all the portions of the metal thin film layer 22 except for portions serving as the electrode pads 24 are removed. For example, the electrode pads 24 are linearly formed with the magnetoresistive elements 20 interposed therebetween. FIG. 33A is a plan view, and FIG. 33B is a diagram illustrating the formed electrode pads 24. Of course, the arrangement of the electrode pads 24 is not limited to that shown in FIGS. 33A and 33B, but the electrode pads 24 extending to the outside in FIGS. 33A and 33B may be disposed at different positions as long as the electrode pads 24 can be linearly arranged.

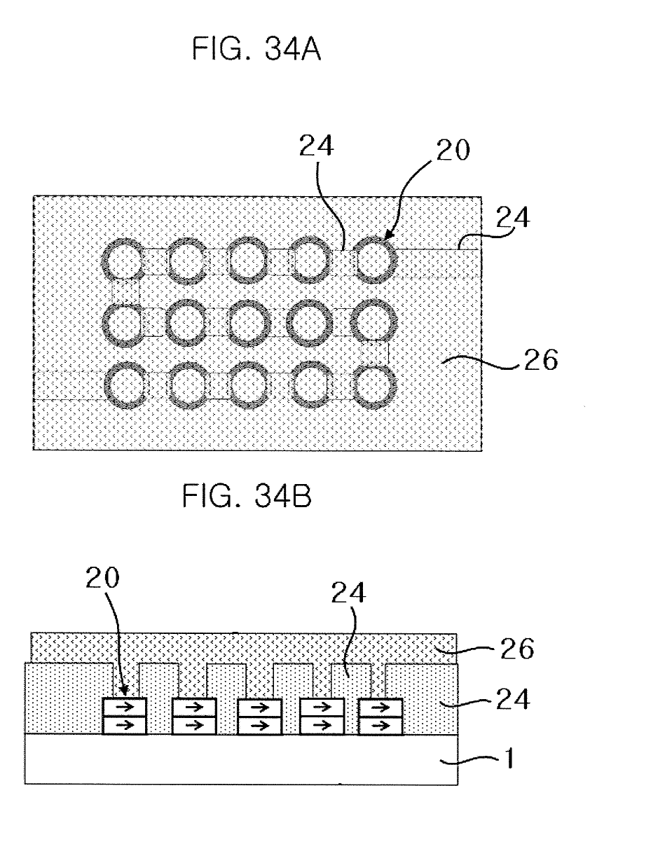

As shown in FIGS. 34A and 34B, an insulating thin film layer 26 is deposited on the substrate 1, the plurality of magnetoresistive elements 20, and the electrode pads 24. The insulating thin film layer 26 is formed of SiO₂ or Si₃N₄. In order to prevent the magnetoresistive elements 20 and the electrode pads 24 from corroded by an analytical solution, for example, SiO₂ or Si₃N₄ is grown with a thickness of about 50 to 300 nm (preferably, 150 nm) by a sputtering deposition method under the conditions of an argon gas pressure of about 3×10⁻⁴ Torr, a sputtering power of about 100 W, and room temperature, thereby forming the SiO₂ or Si₃N₄ insulating thin film layer 26. FIG. 34A is a plan view, and FIG. 34B is a diagram illustrating the formed insulating thin film layer 26.

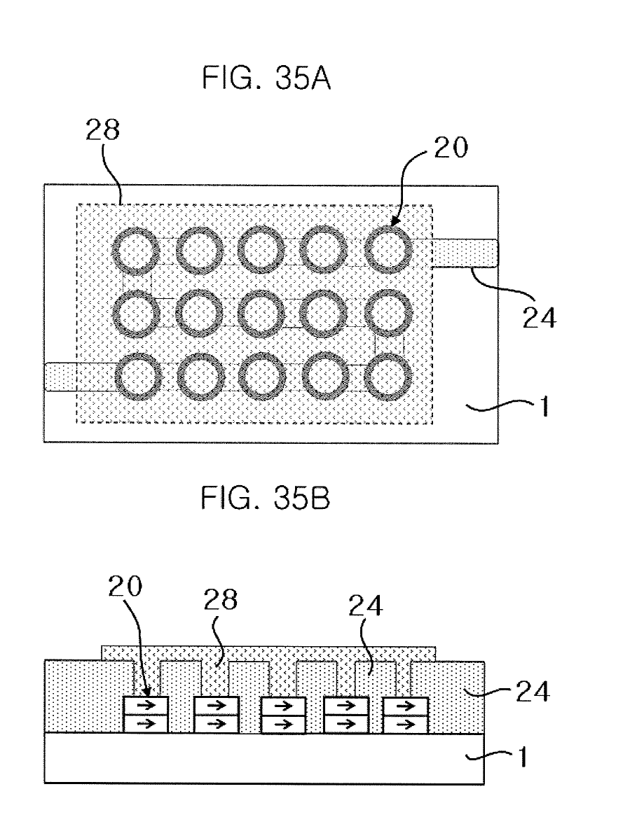

As shown in FIGS. 35A and 35B, the insulating thin film layer 26 is partially removed to form an insulating protective layer 28. All the portions of the insulating thin film layer 26 except a portion serving as the insulating protective layer are removed by a lift-up method, using dry etching, such as an Ar gas ion milling method, or a negative photosensitive mask, thereby forming the insulating protective layer 28. The insulating protective layer 28 covers the entire surface of each of the plurality of magnetoresistive elements 20 and portions of the horizontal electrode pads 24. FIG. 35A is a plan view, and FIG. 35B is a diagram illustrating the formed insulating protective layer 28.

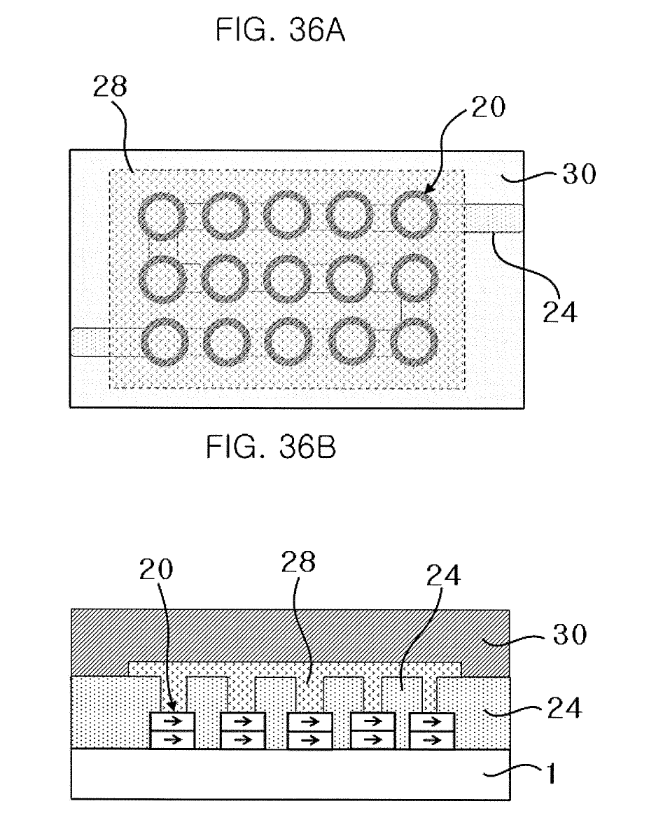

As shown in FIGS. 36A and 36B, a photosensitive magnetic bead thin film 30 is deposited on the substrate 1, the electrode pads 24, and the insulating protective layer 28. The photosensitive magnetic bead thin film 30 is formed with a thickness of about 1 to 2 μm (preferably, about 1.5 μm) at room temperature by spin coating at a speed of about 3000 to 5000 rpm. FIG. 36A is a plan view, and FIG. 36B is a diagram illustrating the deposited photosensitive magnetic bead thin film 30.

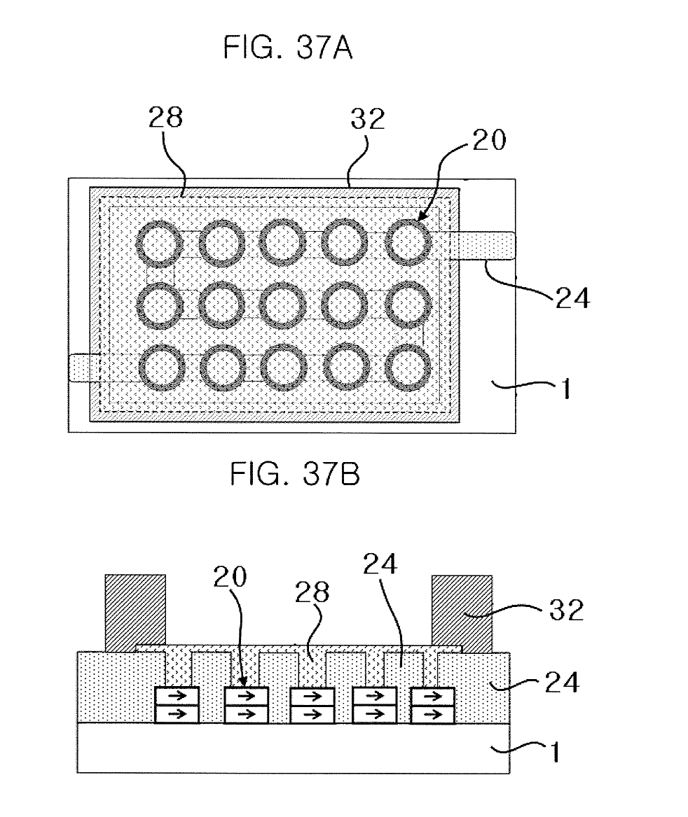

As shown in FIGS. 37A and 37B, the photosensitive magnetic bead thin film 30 is selectively removed to form a magnetic bead limiting layer 32. The magnetic bead limiting layer 32 is formed by removing all the portions of the photosensitive magnetic bead thin film 30 except a portion serving as the magnetic bead limiting layer 32, using a lift-up method and a negative photosensitive mask. The magnetic bead limiting layer 32 can impound a magnetic bead analytical solution therein such that the magnetic bead analytical solution is positioned close to the magnetoresistive element 20. FIG. 37A is a plan view, and FIG. 37B is a diagram illustrating the formed magnetic bead limiting layer 32.

The magnetic field detector manufactured through the above-mentioned processes includes the plurality of magnetoresistive elements 20 with circular ring shapes that are grown on the Si single crystal substrate 1, and the electrodes 24 for applying a current to the plurality of magnetoresistive elements 20 and measuring a horizontal voltage, as shown in FIGS. 37A and 37B. The insulating protective layer 28 is deposited on the entire surface of each of the plurality of magnetoresistive elements 20 and portions of the electrodes 24, and the magnetic bead limiting layer 32 is formed on the plurality of magnetoresistive elements 20, the electrodes 24, and the insulating protective layer 28. The electrodes 24 mean the electrode pads described with reference to FIGS. 33A and 33B, and may be called horizontal electrodes.

In the magnetic field detector according to the fifth embodiment, since a stray field is formed inside the magnetoresistive element having a circular ring shape, the stray field is circulated in the magnetoresistive element, and does not leak to the outside of the element. As a result, there is no mutual interference due to the stray field.

When the magnetic bead is magnetized by a magnetic field applied from the outside, a weak magnetic field is generated, and the generated magnetic field has an effect on the magnetization direction of the free layer, which causes a variation in the output voltage of the magnetoresistive element. The variation in the output voltage makes it possible to detect the magnetic bead.

### Sixth Embodiment

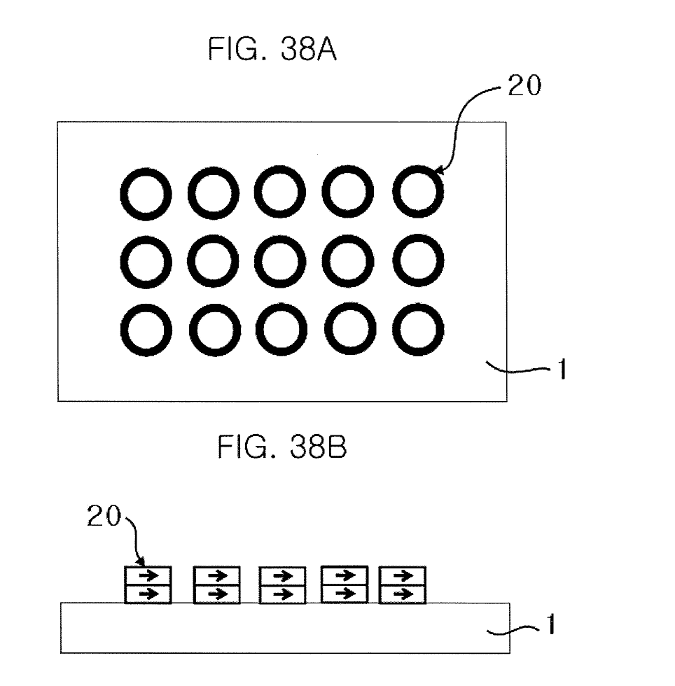

FIGS. 38A to 44B are diagrams sequentially illustrating the structure of a magnetic field detector according to a sixth embodiment of the invention and a method of manufacturing the same. The sixth embodiment differs from the fourth embodiment in that a plurality of magnetoresistive elements having circular ring shapes are arranged in a two-dimensional array (that is, in a matrix). Since a manufacturing method according to the sixth embodiment is most similar to that according to the fourth embodiment, those skilled in the art can easily understand the manufacturing method according to the sixth embodiment.

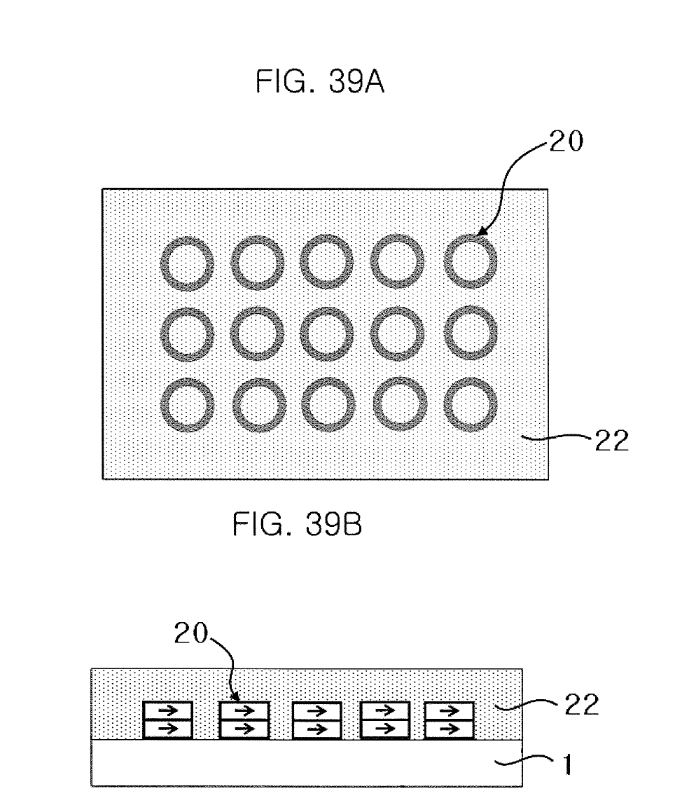

First, a giant magnetoresistive thin film 2 is formed on a substrate 1 by vapor deposition and then etched to form a plurality of magnetoresistive elements 20 with circular ring shapes in a matrix (see FIGS. 38A and 38B). The plurality of magnetoresistive elements 20 are arrayed in a matrix at equal distances. In the etching process, dry etching, such as an Ar gas ion milling method, is performed on the giant magnetoresistive thin film 2 shown in FIG. 1C to etch all the portions of the film except circular ring portions. FIG. 38A is a plan view, and FIG. 39B is a diagram illustrating the arrangement of the substrate 1 and the plurality of magnetoresistive elements 20.

As shown in FIGS. 39A and 39B, a metal thin film layer 22 formed of Au is deposited on the substrate 1 and the plurality of magnetoresistive elements 20. For example, Au is grown with a thickness of about 150 nm by a sputtering deposition method under the conditions of an argon gas pressure of about 3×10⁻⁴ Torr, a sputtering power of about 60 W, and room temperature, thereby forming the metal thin film layer 22. FIG. 39A is a plan view, and FIG. 39B is a diagram illustrating the deposited metal thin film layer 22. The metal thin film layer 22 may be formed of Ta.

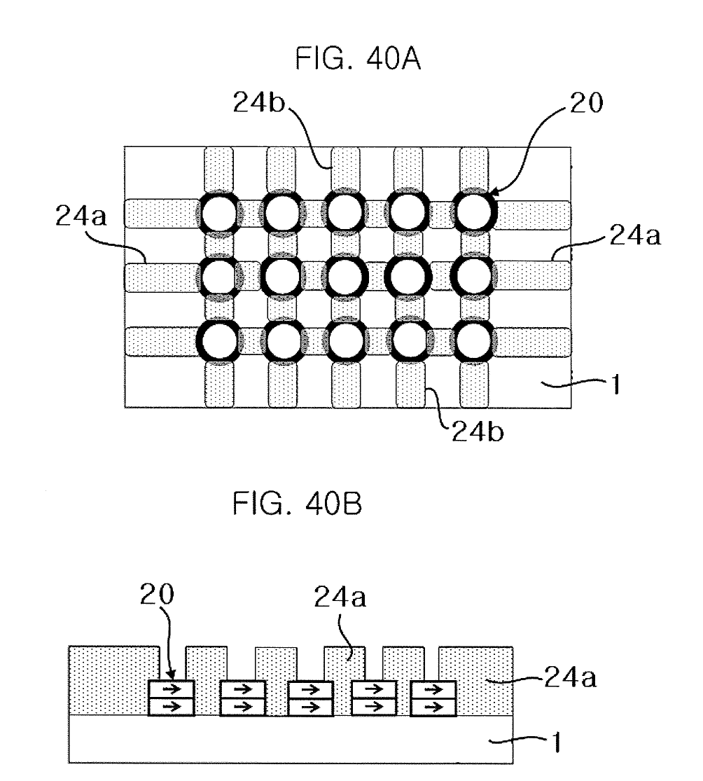

As shown in FIGS. 40A and 40B, horizontal electrode pads 24a and vertical electrode pads 24b are formed. The horizontal electrode pads 24a are used as electrodes for applying a current and measuring a horizontal voltage. The vertical electrode pads 24b are used as electrodes for measuring an output voltage (that is, a vertical voltage) in a direction orthogonal to the direction in which a current flows to the magnetoresistive elements 20. The horizontal and vertical electrode pads 24a and 24b are formed by a lift-up method, using dry etching or a negative photosensitive mask. In this case, all the portions of the metal thin film layer 22 except for portions serving as the electrode pads 24a and 24b are removed. For example, the horizontal electrode pads 24a are formed in the horizontal (row) direction with respect to the magnetoresistive elements 20, and the vertical electrode pads 24b are formed in the vertical (column) direction with respect to the magnetoresistive elements 20. FIG. 40A is a plan view, and FIG. 40B is a diagram illustrating the formed electrode pads 24a and 24b.

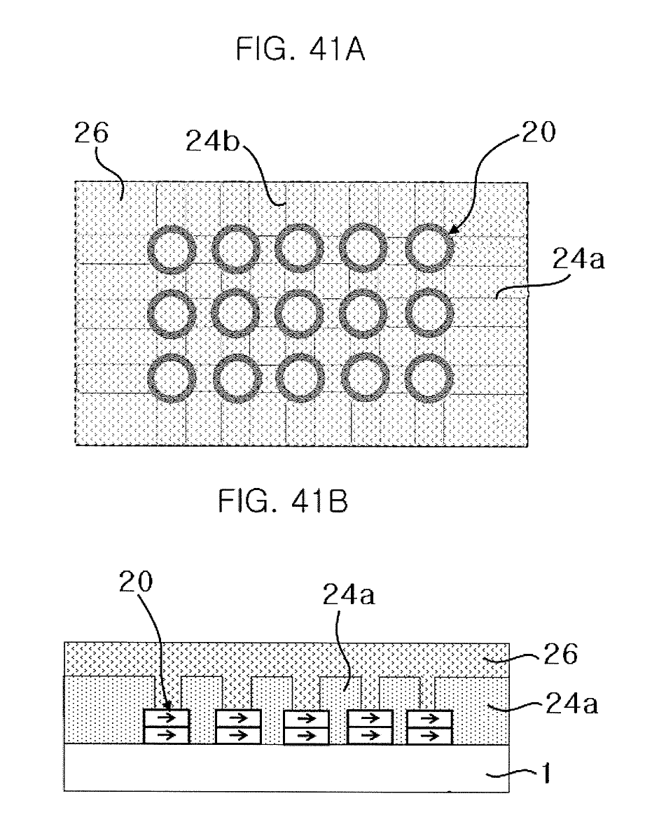

As shown in FIGS. 41A and 41B, an insulating thin film layer 26 is deposited on the substrate 1, the magnetoresistive elements 20, and the electrode pads 24a and 24b. The insulating thin film layer 26 is formed of SiO₂ or Si₃N₄. In order to prevent the magnetoresistive elements 20 and the electrode pads 24a and 24b from being corroded by an analytical solution, for example, SiO₂ or Si₃N₄ is grown with a thickness of about 50 to 300 nm (preferably, 150 nm) by a sputtering deposition method under the conditions of an argon gas pressure of about 3×10⁻⁴ Torr, a sputtering power of about 100 W, and room temperature, thereby forming the SiO₂ or Si₃N₄ insulating thin film layer 26. FIG. 41A is a plan view, and FIG. 41B is a diagram illustrating the formed insulating thin film layer 26.

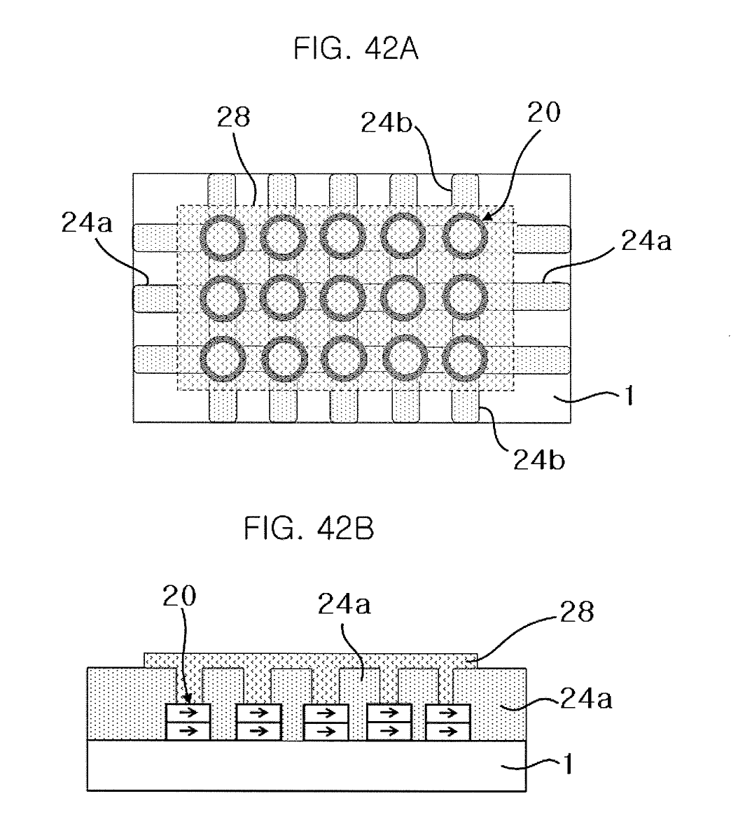

As shown in FIGS. 42A and 42B, the insulating thin film layer 26 is partially removed to form an insulating protective layer 28. All the portions of the insulating thin film layer 26 except a portion serving as the insulating protective layer are removed by a lift-up method, using dry etching, such as an Ar gas ion milling method, or a negative photosensitive mask, thereby forming the insulating protective layer 28. FIG. 42A is a plan view, and FIG. 42B is a diagram illustrating the formed insulating protective layer 28.

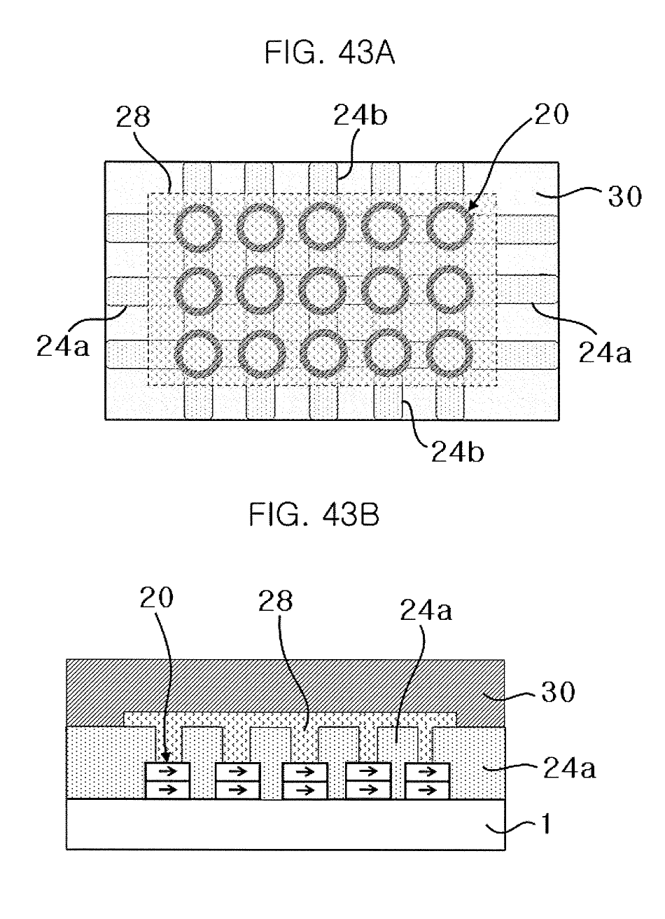

As shown in FIGS. 43A and 43B, a photosensitive magnetic bead thin film 30 is deposited on the substrate 1, the electrode pads 24a and 24b, and the insulating protective layer 28. The photosensitive magnetic bead thin film 30 is formed with a thickness of about 1 to 2 μm (preferably, about 1.5 μm) at room temperature by spin coating at a speed of about 3000 to 5000 rpm. FIG. 43A is a plan view, and FIG. 43B is a diagram illustrating the deposited photosensitive magnetic bead thin film 30.

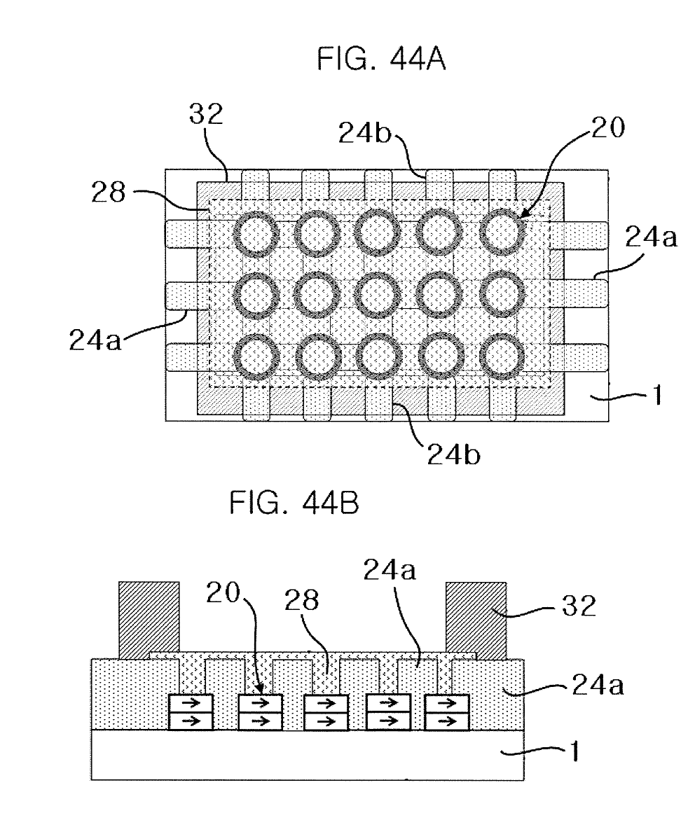

As shown in FIGS. 44A and 44B, the photosensitive magnetic bead thin film 30 is selectively removed to form a magnetic bead limiting layer 32. The magnetic bead limiting layer 32 is formed by removing all the portions of the photosensitive magnetic bead thin film 30 except a portion serving as the magnetic bead limiting layer 32, using a lift-up method and a negative photosensitive mask. The magnetic bead limiting layer 32 can impound a magnetic bead analytical solution therein such that the magnetic bead analytical solution is positioned close to the magnetoresistive element 20. FIG. 44A is a plan view and FIG. 44B is a diagram illustrating the formed magnetic bead limiting layer 32.

The magnetic field detector manufactured through the above-mentioned processes includes the plurality of magnetoresistive elements 20 with circular ring shapes that are grown on the Si single crystal substrate 1, the horizontal electrodes 24a for applying a current to the plurality of magnetoresistive elements 20 and measuring a horizontal voltage, and the vertical electrodes 24b for measuring a vertical voltage, as shown in FIGS. 44A and 44B. The insulating protective layer 28 is deposited on the entire surface of each of the plurality of magnetoresistive elements 20 and portions of the electrodes 24a and 24b, and the magnetic bead limiting layer 32 is formed on the plurality of magnetoresistive elements 20, the electrodes 24a and 24b, and the insulating protective layer 28. The horizontal electrodes 24a mean the horizontal electrode pads described with reference to FIGS. 40A and 40B, and the vertical electrodes 24b mean the vertical electrode pads described with reference to FIGS. 40A and 40B.

In the magnetic field detector according to the sixth embodiment, since a stray field is formed inside the magnetoresistive element having a circular ring shape, the stray field is circulated in the magnetoresistive element, but does not leak to the outside of the element. As a result, there is no mutual interference due to the stray field.

When the magnetic bead is magnetized by a magnetic field applied from the outside, a weak magnetic field is generated, and the generated magnetic field has an effect on the magnetization direction of the free layer, which causes a variation in the output voltage of the magnetoresistive element. The variation in the output voltage makes it possible to detect the magnetic bead.

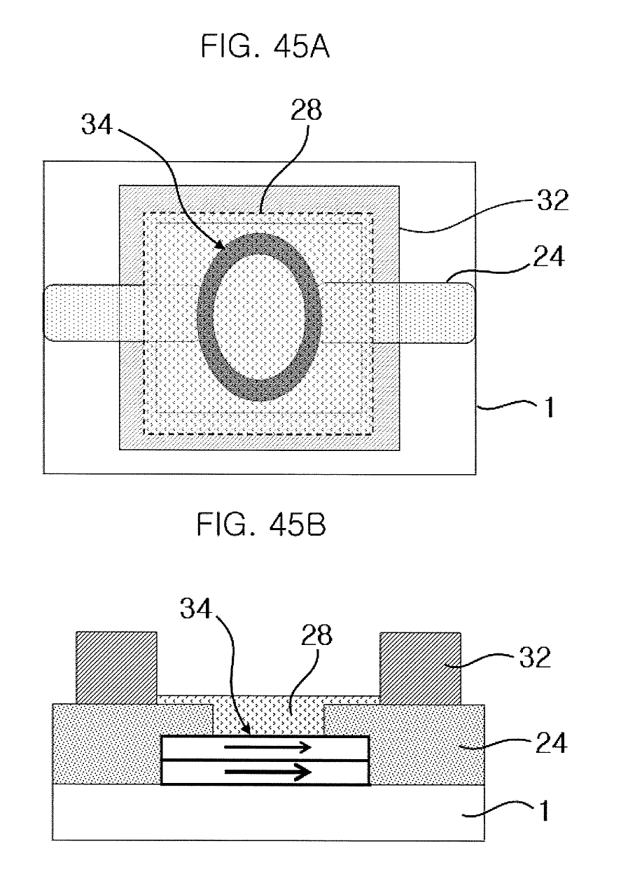

FIGS. 45A and 45B are diagrams illustrating a modification of the first embodiment. A magnetoresistive element shown in FIGS. 45A and 45B is similar to the first embodiment except that it has an elliptical ring shape, and the magnetoresistive element is manufactured by the same method as that according to the first embodiment. In FIGS. 45A and 45B, reference numeral 34 denotes the magnetoresistive element with the elliptical ring shape. FIG. 45A is a plan view, and FIG. 45B is a diagram illustrating a magnetic field detector including the magnetoresistive element 34 with the elliptical ring shape. For example, the length of the major axis of the magnetoresistive element 34 is in a range of about 100 nm to 30 μm, and the width of a ring of the magnetoresistive element 34 is in a range of about 100 nm to 5 μm. The ratio of the length of the minor axis to the length of the major axis of the magnetoresistive element 34 is in a range of about 1:2 to 1:3. The dimensions of the magnetoresistive element 34 may be applied to the following other modifications. Of course, the dimensions of the magnetoresistive element 34 are just illustrative, but the invention is not limited thereto.

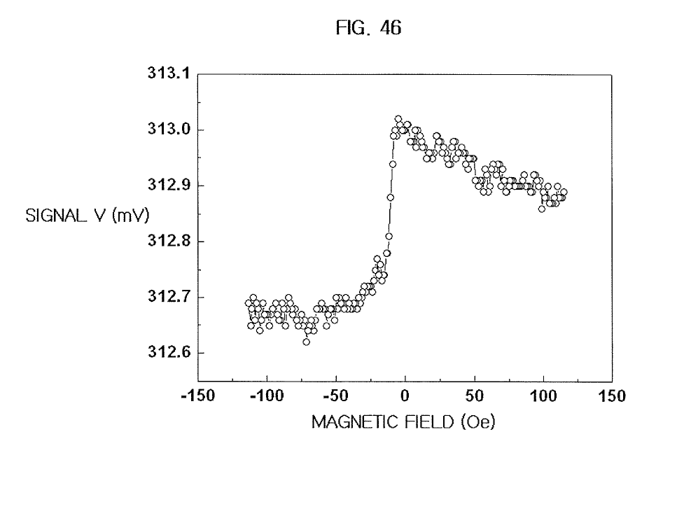

FIG. 46 is a graph illustrating the relationships between a voltage and a magnetic field applied to the magnetic field detector provided with the magnetoresistive element having an elliptical ring shape. As can be seen from FIG. 46, a rapid voltage variation occurs when the strength of the external magnetic field is around 0 (zero) oersted (Oe). This result proves that the magnetic field detector manufactured by the above-mentioned manufacturing method can detect a very weak magnetic field.

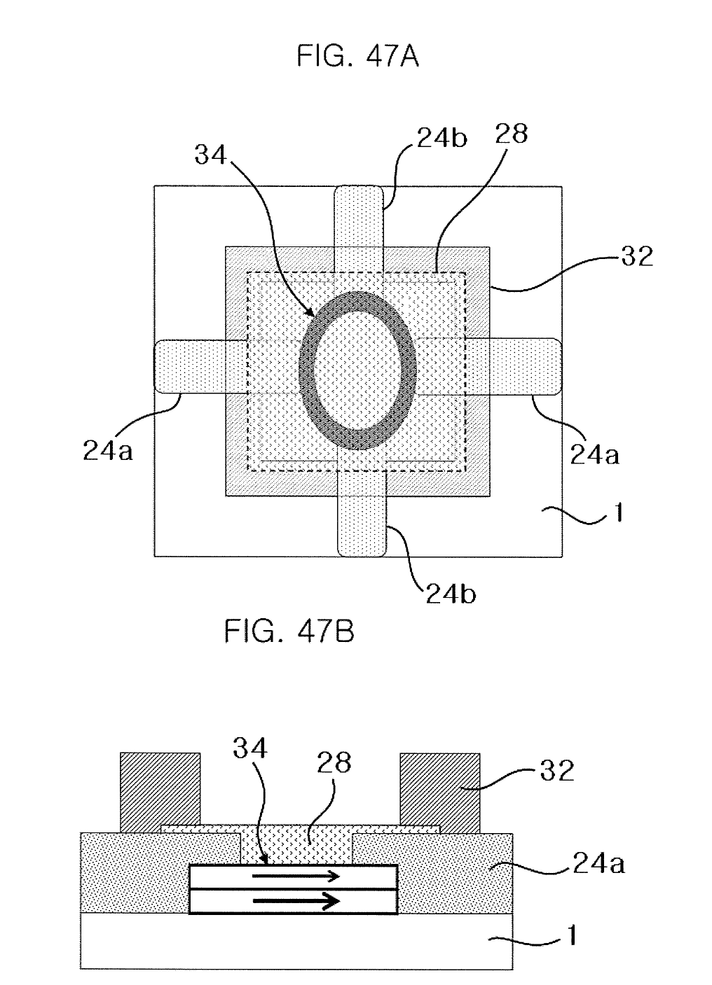

FIGS. 47A and 47B are diagrams illustrating a modification of the second embodiment. A magnetoresistive element shown in FIGS. 47A and 47B is similar to the second embodiment except that it has an elliptical ring shape, and the magnetoresistive element is manufactured by the same method as that according to the second embodiment. In FIGS. 47A and 47B, reference numeral 34 denotes the magnetoresistive element with the elliptical ring shape. FIG. 47A is a plan view, and FIG. 47B is a diagram illustrating a magnetic field detector including the magnetoresistive element 34 with the elliptical ring shape.

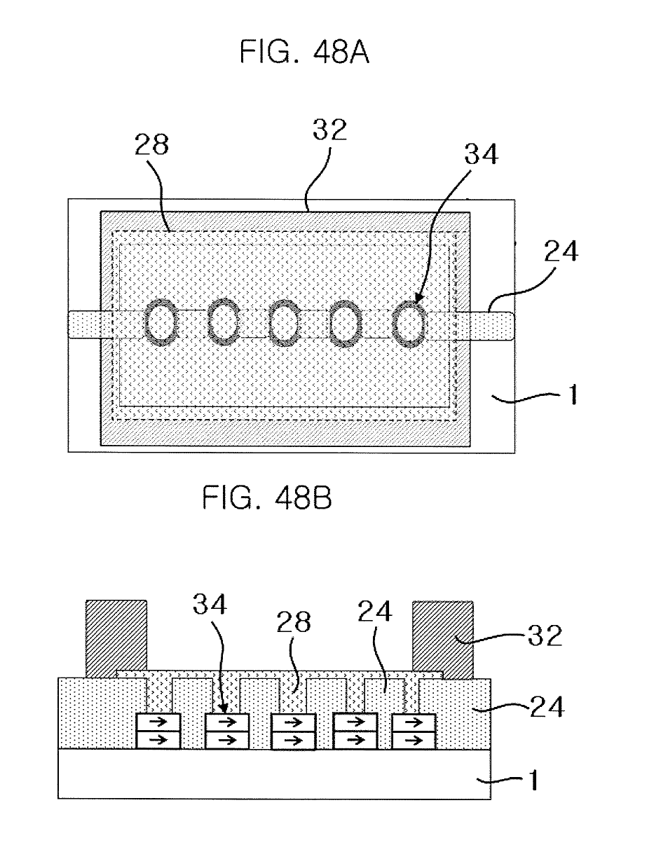

FIGS. 48A and 48B are diagrams illustrating a modification of the third embodiment. A magnetoresistive element shown in FIGS. 48A and 48B is similar to the third embodiment except that it has an elliptical ring shape, and the magnetoresistive element is manufactured by the same method as that according to the third embodiment. In FIGS. 48A and 48B, reference numeral 34 denotes the magnetoresistive element with the elliptical ring shape. FIG. 48A is a plan view, and FIG. 48B is a diagram illustrating a magnetic field detector including the magnetoresistive element 34 with the elliptical ring shape.

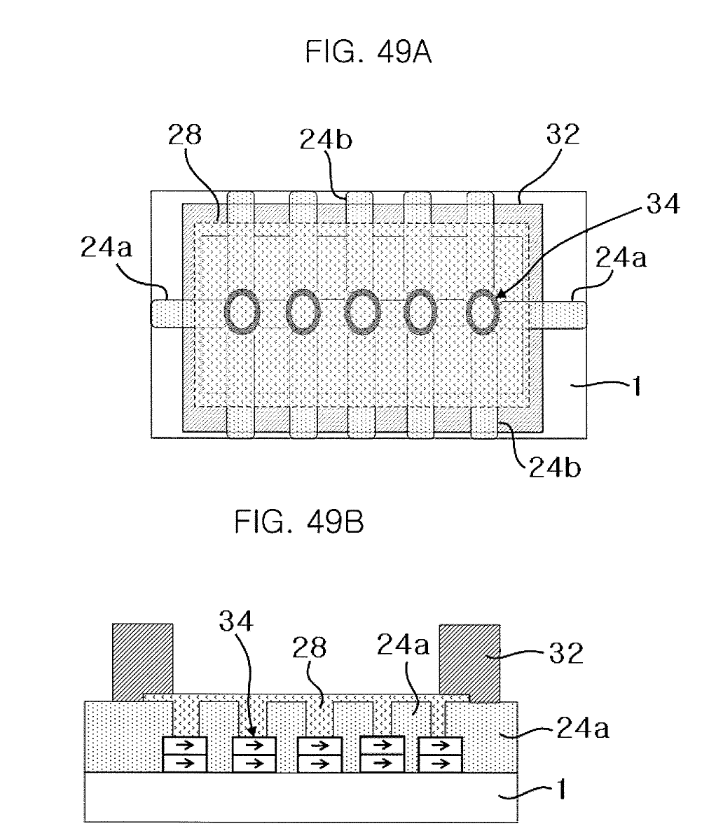

FIGS. 49A and 49B are diagrams illustrating a modification of the fourth embodiment. A magnetoresistive element shown in FIGS. 49A and 49B is similar to the fourth embodiment except that it has an elliptical ring shape, and the magnetoresistive element is manufactured by the same method as that according to the fourth embodiment. In FIGS. 49A and 49B, reference numeral 34 denotes the magnetoresistive element with the elliptical ring shape. FIG. 49A is a plan view, and FIG. 49B is a diagram illustrating a magnetic field detector including the magnetoresistive element 34 with the elliptical ring shape.

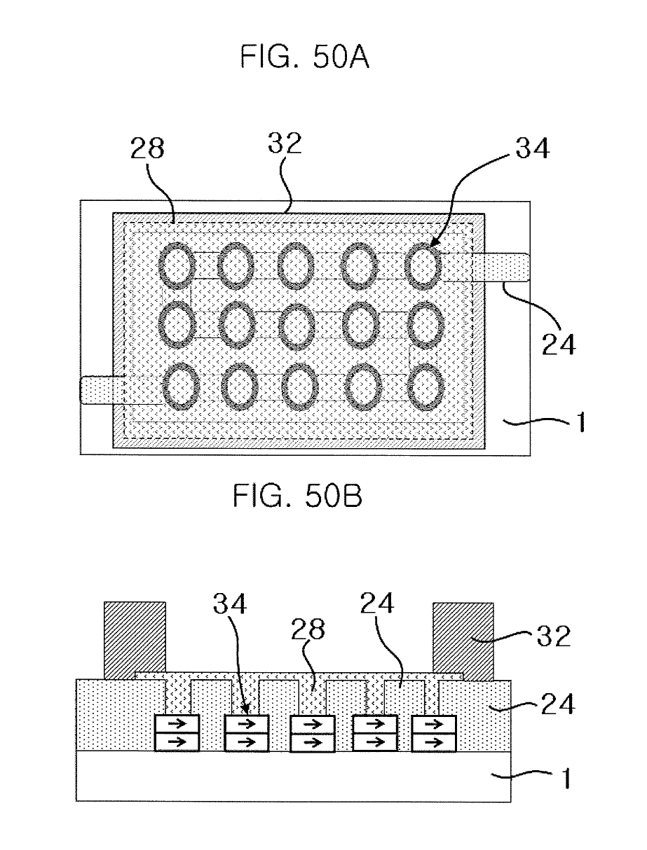

FIGS. 50A and 50B are diagrams illustrating a modification of the fifth embodiment. A magnetoresistive element shown in FIGS. 50A and 50B is similar to the fifth embodiment except that it has an elliptical ring shape, and the magnetoresistive element is manufactured by the same method as that according to the fifth embodiment. In FIGS. 50A and 50B, reference numeral 34 denotes the magnetoresistive element with the elliptical ring shape. FIG. 50A is a plan view, and FIG. 50B is a diagram illustrating a magnetic field detector including the magnetoresistive element 34 with the elliptical ring shape.

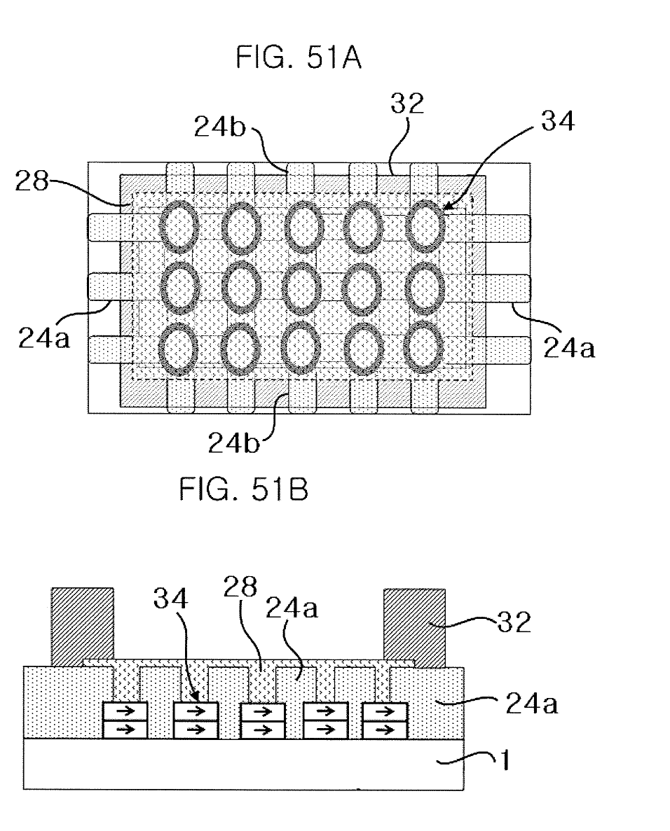

FIGS. 51A and 51B are diagrams illustrating a modification of the sixth embodiment. A magnetoresistive element shown in FIGS. 51A and 51B is similar to the sixth embodiment except that it has an elliptical ring shape, and the magnetoresistive element is manufactured by the same method as that according to the sixth embodiment. In FIGS. 51A and 51B, reference numeral 34 denotes the magnetoresistive element with the elliptical ring shape. FIG. 51A is a plan view, and FIG. 51B is a diagram illustrating a magnetic field detector including the magnetoresistive element 34 with the elliptical ring shape.

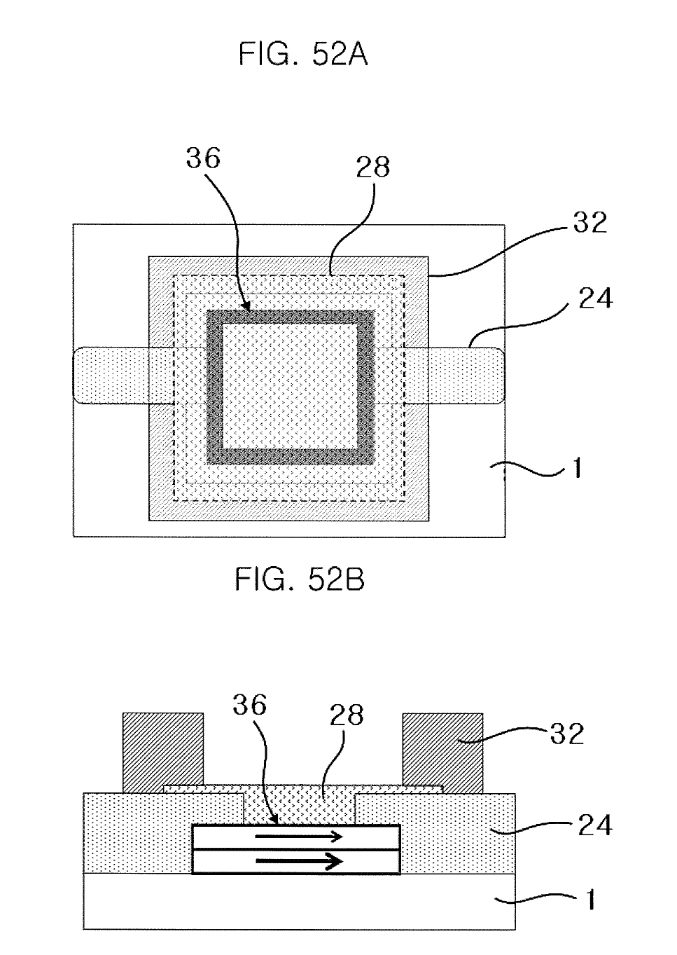

FIGS. 52A and 52B are diagrams illustrating another modification of the first embodiment. A magnetoresistive element shown in FIGS. 52A and 52B is similar to the first embodiment except that it has a square ring shape, and the magnetoresistive element is manufactured by the same method as that according to the first embodiment. In FIGS. 52A and 52B, reference numeral 36 denotes the magnetoresistive element with the square ring shape. FIG. 52A is a plan view, and FIG. 52B is a diagram illustrating a magnetic field detector including the magnetoresistive element 36 with the square ring shape. For example, the length of a side of the magnetoresistive element 36 is in a range of about 100 nm to 30 μm, and the width of a ring of the magnetoresistive element 36 is in a range of about 100 nm to 5 μm. The dimensions of the magnetoresistive element 36 may be applied to the following other modifications. Of course, the dimensions of the magnetoresistive element 36 are just illustrative, but the invention is not limited thereto.

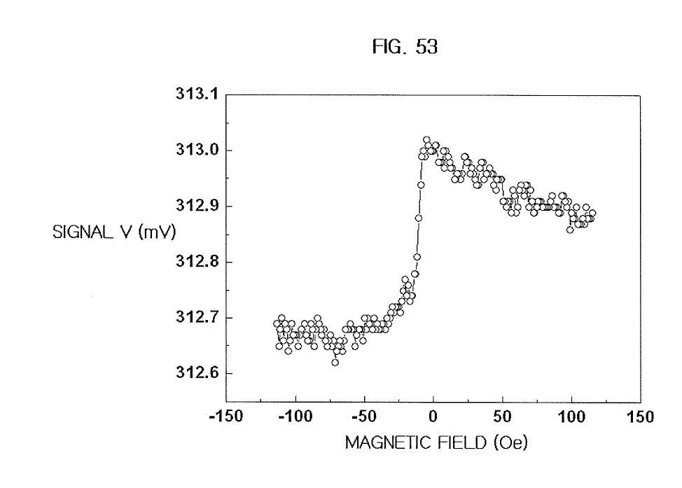

FIG. 53 is a graph illustrating the relationships between a voltage and a magnetic field applied to the magnetic field detector provided with the magnetoresistive element having a square ring shape. As can be seen from FIG. 53, a rapid voltage variation occurs when the strength of the external magnetic field is around 0 (zero) oersted (Oe). This result proves that the magnetic field detector manufactured by the above-mentioned manufacturing method can detect a very weak magnetic field.

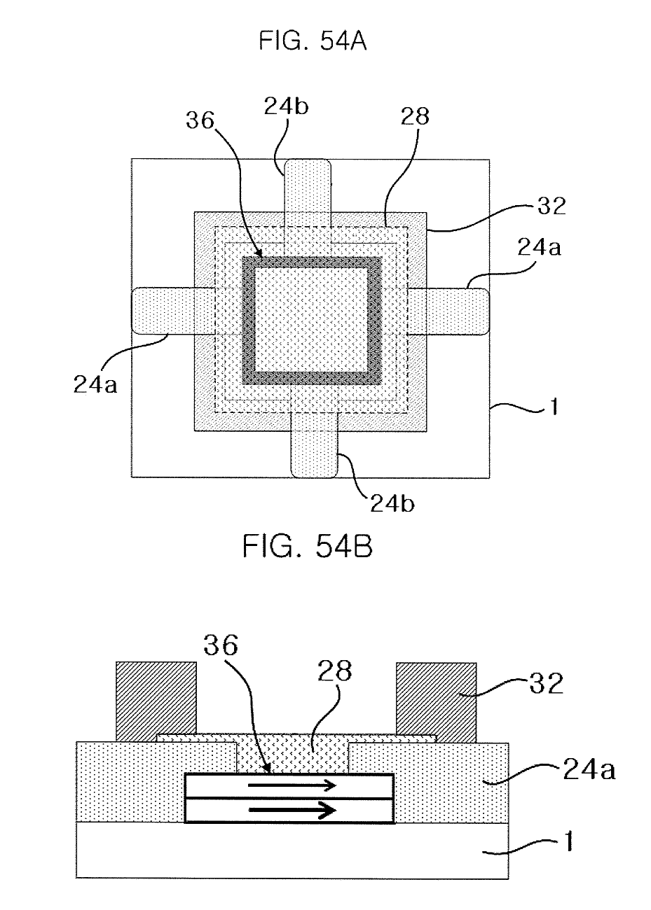

FIGS. 54A and 54B are diagrams illustrating another modification of the second embodiment. A magnetoresistive element shown in FIGS. 54A and 54B is similar to the second embodiment except that it has a square ring shape, and the magnetoresistive element is manufactured by the same method as that according to the second embodiment. In FIGS. 54A and 54B, reference numeral 36 denotes the magnetoresistive element with the square ring shape. FIG. 54A is a plan view, and FIG. 54B is a diagram illustrating a magnetic field detector including the magnetoresistive element 36 with the square ring shape.

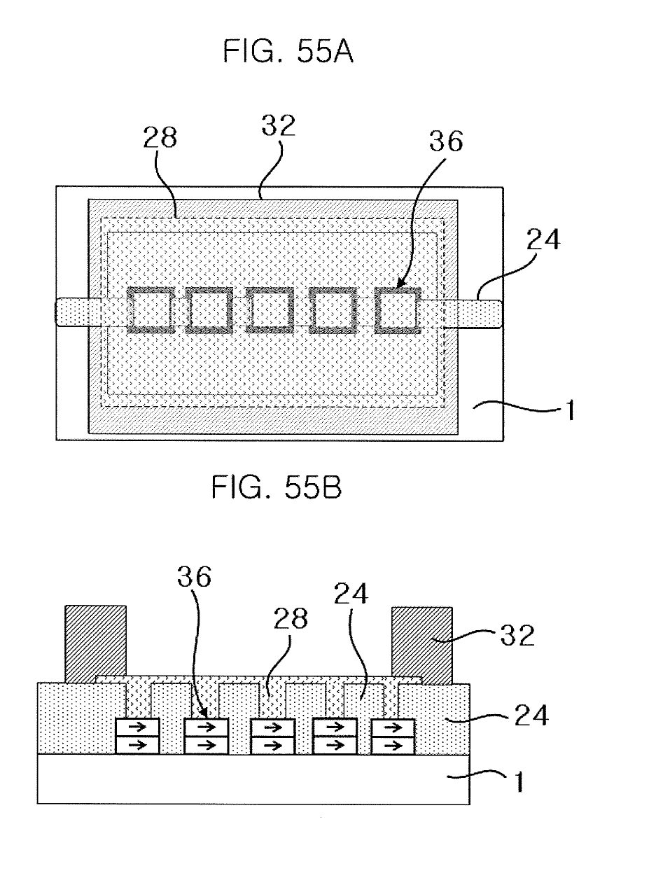

FIGS. 55A and 55B are diagrams illustrating another modification of the third embodiment. A magnetoresistive element shown in FIGS. 55A and 55B is similar to the third embodiment except that it has a square ring shape, and the magnetoresistive element is manufactured by the same method as that according to the third embodiment. In FIGS. 55A and 55B, reference numeral 36 denotes the magnetoresistive element with the square ring shape. FIG. 55A is a plan view, and FIG. 55B is a diagram illustrating a magnetic field detector including the magnetoresistive element 36 with the square ring shape.

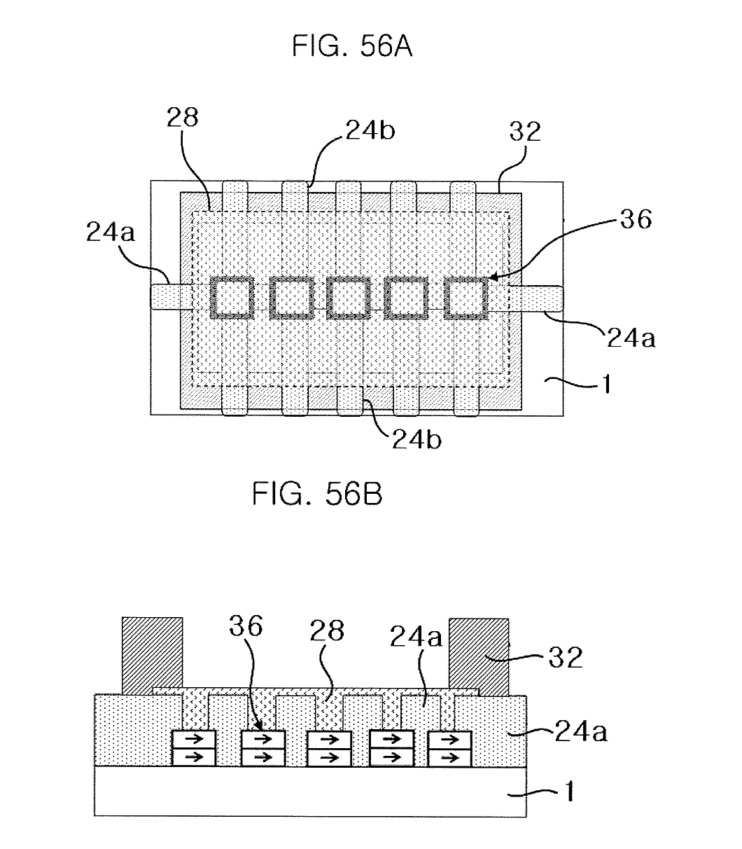

FIGS. 56A and 56B are diagrams illustrating another modification of the fourth embodiment. A magnetoresistive element shown in FIGS. 56A and 56B is similar to the fourth embodiment except that it has a square ring shape, and the magnetoresistive element is manufactured by the same method as that according to the fourth embodiment. In FIGS. 56A and 56B, reference numeral 36 denotes the magnetoresistive element with the square ring shape. FIG. 56A is a plan view, and FIG. 56B is a diagram illustrating a magnetic field detector including the magnetoresistive element 34 with the square ring shape.

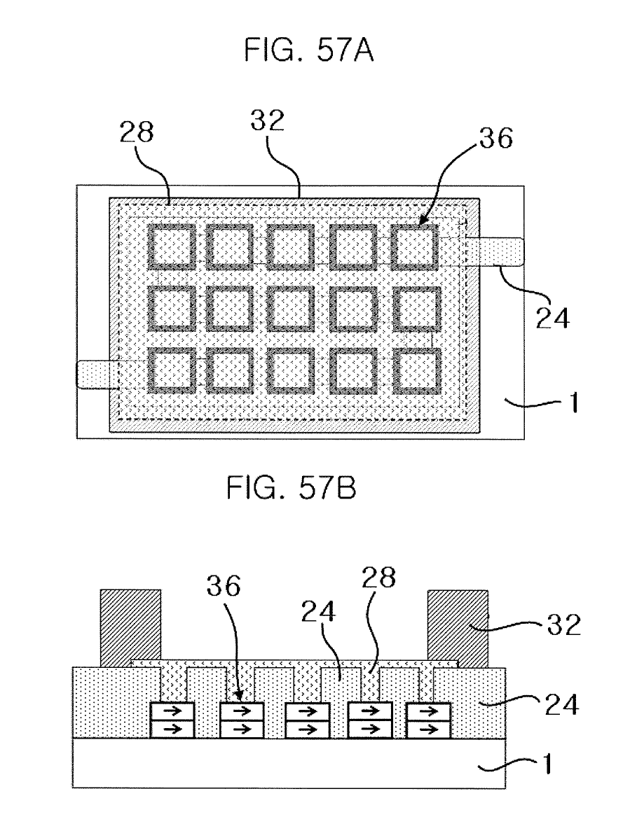

FIGS. 57A and 57B are diagrams illustrating another modification of the fifth embodiment. A magnetoresistive element shown in FIGS. 57A and 57B is similar to the fifth embodiment except that it has a square ring shape, and the magnetoresistive element is manufactured by the same method as that according to the fifth embodiment. In FIGS. 57A and 57B, reference numeral 36 denotes the magnetoresistive element with the square ring shape. FIG. 57A is a plan view, and FIG. 57B is a diagram illustrating a magnetic field detector including the magnetoresistive element 36 with the square ring shape.

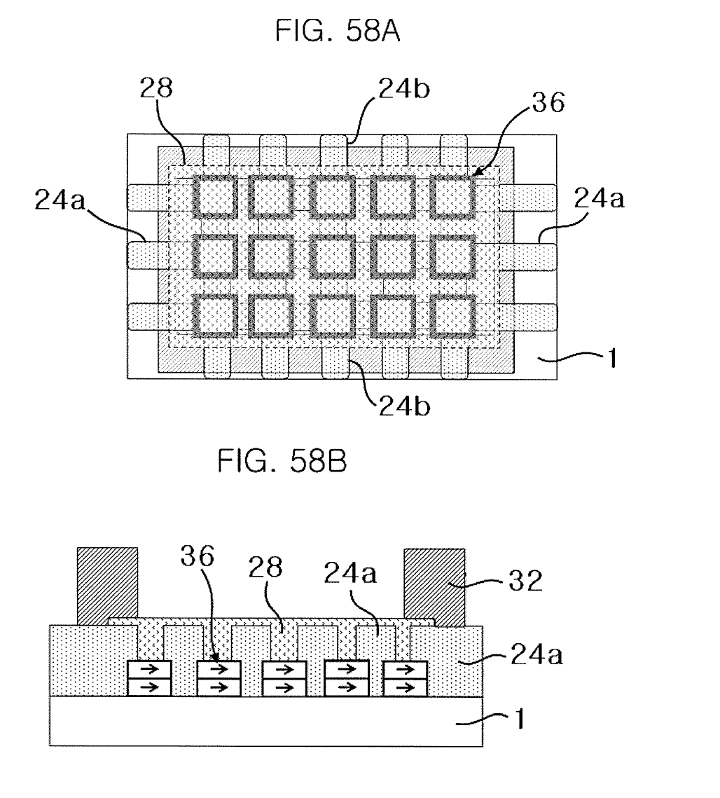

FIGS. 58A and 58B are diagrams illustrating another modification of the sixth embodiment. A magnetoresistive element shown in FIGS. 58A and 58B is similar to the sixth embodiment except that it has a square ring shape, and the magnetoresistive element is manufactured by the same method as that according to the sixth embodiment. In FIGS. 58A and 58B, reference numeral 36 denotes the magnetoresistive element with the square ring shape. FIG. 58A is a plan view, and FIG. 58B is a diagram illustrating a magnetic field detector including the magnetoresistive element 36 with the square ring shape.

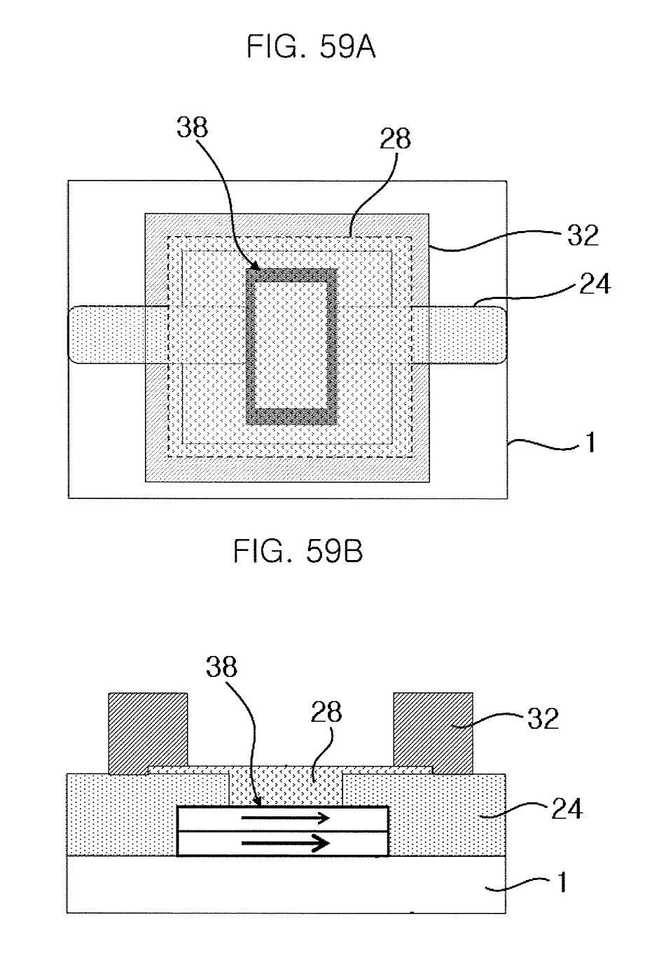

FIGS. 59A and 59B are diagrams illustrating still another modification of the first embodiment. A magnetoresistive element shown in FIGS. 59A and 59B is similar to the first embodiment except that it has a rectangular ring shape, and the magnetoresistive element is manufactured by the same method as that according to the first embodiment. In FIGS. 59A and 59B, reference numeral 38 denotes the magnetoresistive element with the rectangular ring shape. FIG. 59A is a plan view, and FIG. 59B is a diagram illustrating a magnetic field detector including the magnetoresistive element 38 with the rectangular ring shape. For example, the length of the magnetoresistive element 38 is in a range of about 100 nm to 30 μm, and the width of a ring of the magnetoresistive element 38 is in a range of about 100 nm to 5 μm. The ratio of the width and the length of the magnetoresistive element 38 is in a range of about 1:1 to 1:3. The dimensions of the magnetoresistive element 38 may be applied to the following other modifications. Of course, the dimensions of the magnetoresistive element 38 are just illustrative, but the invention is not limited thereto.

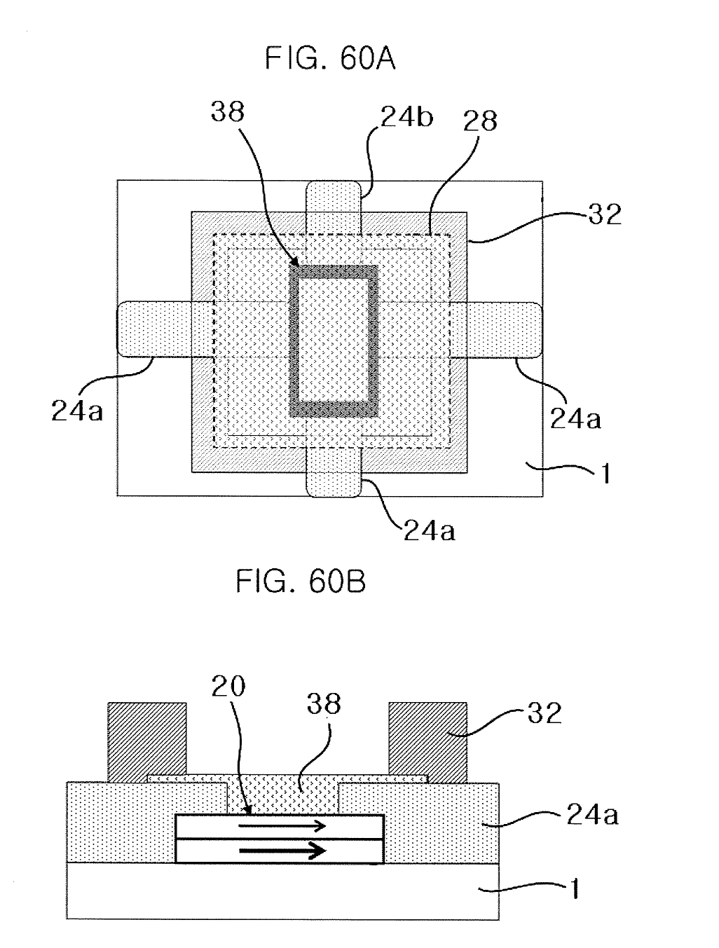

FIGS. 60A and 60B are diagrams illustrating still another modification of the second embodiment. A magnetoresistive element shown in FIGS. 60A and 60B is similar to the second embodiment except that it has a rectangular ring shape, and the magnetoresistive element is manufactured by the same method as that according to the second embodiment. In FIGS. 60A and 60B, reference numeral 38 denotes the magnetoresistive element with the rectangular ring shape. FIG. 60A is a plan view, and FIG. 60B is a diagram illustrating a magnetic field detector including the magnetoresistive element 38 with the rectangular ring shape.

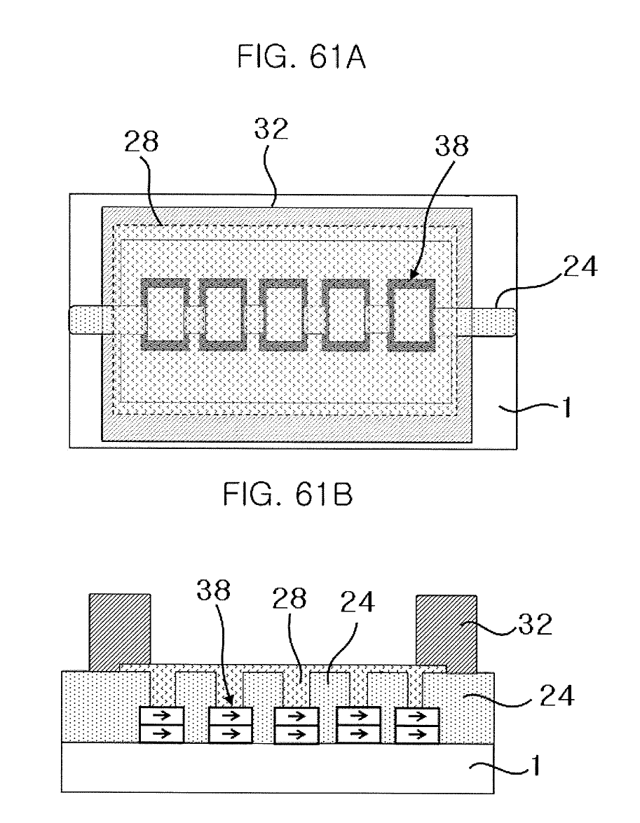

FIGS. 61A and 61B are diagrams illustrating still another modification of the third embodiment. A magnetoresistive element shown in FIGS. 61A and 61B is similar to the third embodiment except that it has a rectangular ring shape, and the magnetoresistive element is manufactured by the same method as that according to the third embodiment. In FIGS. 61A and 61B, reference numeral 38 denotes the magnetoresistive element with the rectangular ring shape. FIG. 61A is a plan view, and FIG. 61B is a diagram illustrating a magnetic field detector including the magnetoresistive element 38 with the rectangular ring shape.

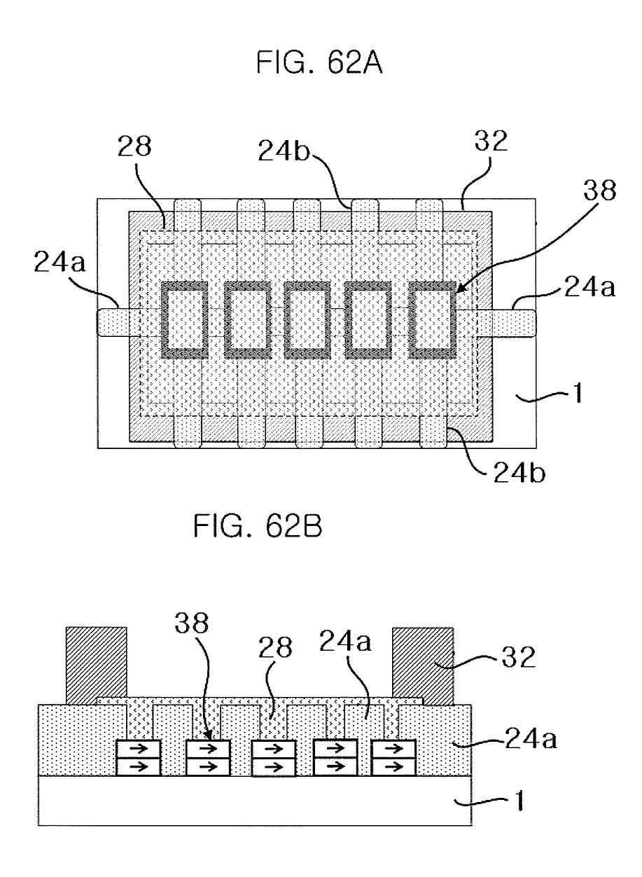

FIGS. 62A and 62B are diagrams illustrating still another modification of the fourth embodiment. A magnetoresistive element shown in FIGS. 62A and 62B is similar to the fourth embodiment except that it has a rectangular ring shape, and the magnetoresistive element is manufactured by the same method as that according to the fourth embodiment. In FIGS. 62A and 62B, reference numeral 38 denotes the magnetoresistive element with the rectangular ring shape. FIG. 62A is a plan view, and FIG. 62B is a diagram illustrating a magnetic field detector including the magnetoresistive element 38 with the rectangular ring shape.

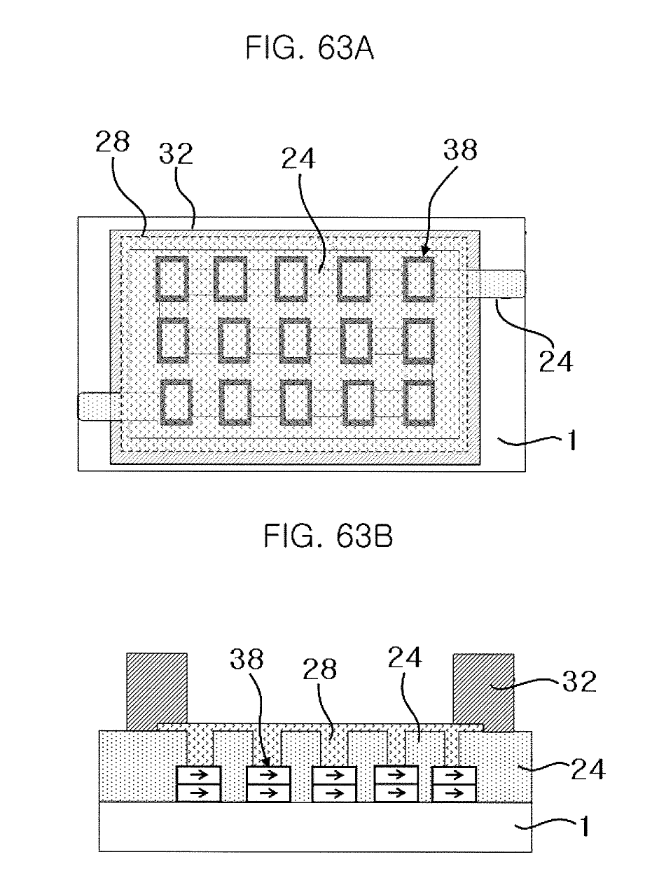

FIGS. 63A and 63B are diagrams illustrating still another modification of the fifth embodiment. A magnetoresistive element shown in FIGS. 63A and 63B is similar to the fifth embodiment except that it has a rectangular ring shape, and the magnetoresistive element is manufactured by the same method as that according to the fifth embodiment. In FIGS. 63A and 63B, reference numeral 38 denotes the magnetoresistive element with the rectangular ring shape. FIG. 63A is a plan view, and FIG. 63B is a diagram illustrating a magnetic field detector including the magnetoresistive element 38 with the rectangular ring shape.

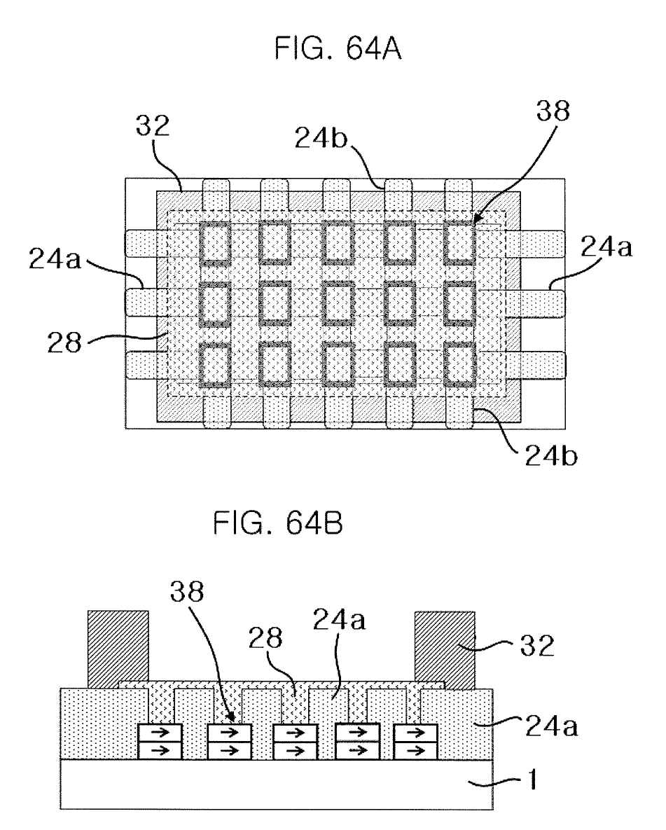

FIGS. 64A and 64B are diagrams illustrating still another modification of the sixth embodiment. A magnetoresistive element shown in FIGS. 64A and 64B is similar to the sixth embodiment except that it has a rectangular ring shape, and the magnetoresistive element is manufactured by the same method as that according to the sixth embodiment. In FIGS. 64A and 64B, reference numeral 38 denotes the magnetoresistive element with the rectangular ring shape. FIG. 64A is a plan view, and FIG. 64B is a diagram illustrating a magnetic field detector including the magnetoresistive element 38 with the rectangular ring shape.

In the magnetic field detectors according to the above-described modifications, since a stray field is formed inside the magnetoresistive elements having the elliptical, square, and rectangular ring shapes, the stray field is circulated in the magnetoresistive elements, but does not leak to the outside of the elements. As a result, there is no mutual interference due to the stray field.

When the magnetic bead is magnetized by a magnetic field applied from the outside, a weak magnetic field is generated, and the generated magnetic field has an effect on the magnetization direction of the free layer, which causes a variation in the output voltage of the magnetoresistive element. The variation in the output voltage makes it possible to detect the magnetic bead.

In the above-described embodiments and modifications, as the size of the magnetoresistive element decreases, magnetic bead sensing capability (that is, sensitivity) is improved. However, when the size of the magnetoresistive element is excessively small, it is difficult to actually manufacture a magnetic field detector. Therefore, the above-mentioned dimensions of the magnetoresistive element are determined in consideration of the current capability of manufacturing the element and sensitivity. Of course, when the element manufacturing capability is improved, it may be possible to further reduce the size of the magnetoresistive element. In addition, sensitivity for sensing the magnetic bead is lowered when the size of the magnetoresistive element is out of the above-described numerical range.

While the invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims. In the above-described embodiments and modifications, the magnetoresistive elements are formed in a circular ring shape, an elliptical ring shape, a square ring shape, and a rectangular ring shape. However, the magnetoresistive elements may be formed in various shapes, such as a pentagonal ring shape, a hexagonal ring shape, and an octagonal ring shape, as long as they can have ring shapes and electrodes can be provided.

What is claimed is:

1. A magnetic field detector comprising:
a magnetoresistive element that is formed in any one of a circular ring shape, an elliptical ring shape, a square ring shape, and a rectangular ring shape.

2. A magnetic field detector using a thin film for detecting magnetic beads, the magnetic field detector comprising:
a substrate;
a magnetoresistive element that is formed on an upper surface of the substrate in a ring shape using the thin film;
electrodes that are formed on the upper surface of the substrate to be connected to the magnetoresistive element;
a protective layer that is formed on the magnetoresistive element and the electrodes; and
a magnetic bead limiting layer that is formed on an upper surface of the protective layer to cover the entire surface of the magnetoresistive element and portions of the electrodes.

3. The magnetic field detector of claim 2,
wherein the thin film is formed of any one of a giant magnetoresistive thin film, an anisotropic magnetoresistive thin film, a spin valve thin film, and a tunnel-type magnetoresistive thin film.

4. The magnetic field detector of claim 2,
wherein the thin film includes a pinned layer and a free layer.

5. The magnetic field detector of claim 2,
wherein the thin film is a laminate of a seed layer, an antiferromegnetic layer, a pinned layer, a gap layer, a free layer, and a protective layer formed in this order.

6. The magnetic field detector of claim 2,
wherein the magnetoresistive element is formed in any one of a circular ring shape, an elliptical ring shape, a square ring shape, and a rectangular ring shape.

7. The magnetic field detector of claim 2,
wherein the electrodes are formed of Ta or Au.

8. The magnetic field detector of claim 2,
wherein the electrodes are formed so as to be horizontally connected to the magnetoresistive element.

9. The magnetic field detector of claim 2,
wherein the electrodes are formed so as to be vertically and horizontally connected to the magnetoresistive element.

10. The magnetic field detector of claim 2,
wherein the protective layer is formed of SiO₂ or Si₃N₄.

11. The magnetic field detector of claim 2,
wherein the protective layer is formed with a thickness of 50 to 300 nm at room temperature.

12. The magnetic field detector of claim 2,
wherein the magnetic bead limiting layer is formed of a photosensitive thin film.

13. The magnetic field detector of claim 2,
wherein the magnetic bead limiting layer is formed with a thickness of 1 to 2 μm at room temperature.

14. The magnetic field detector of claim 2,
wherein the outside diameter of the magnetoresistive element is in a range of 100 nm to 30 μm.

15. The magnetic field detector of claim 2,
wherein the width of the magnetoresistive element is in a range of 100 nm to 5 μm.

16. The magnetic field detector of claim 2,
wherein a plurality of magnetoresistive elements are formed in a one-dimensional array.

17. The magnetic field detector of claim 2,
wherein a plurality of magnetoresistive elements are formed in a two-dimensional array, that is, in a matrix.
